(19) United States
(12) Patent Application Publication
(10) Pub. No.: US 2025/0142804 A1
(43) Pub. Date: May 1, 2025

(54) SEMICONDUCTOR DEVICES INCLUDING THROUGH-PLUGS

(71) Applicant: Samsung Electronics Co., Ltd., Suwon-si (KR)

(72) Inventors: Iljae SHIN, Suwon-si (KR); Kiseok LEE, Suwon-si (KR); Seokhan PARK, Suwon-si (KR); Sungmin PARK, Suwon-si (KR); Dongjun LEE, Suwon-si (KR)

(73) Assignee: Samsung Electronics Co., Ltd., Suwon-si (KR)

(21) Appl. No.: 18/734,052

(22) Filed: Jun. 5, 2024

(30) Foreign Application Priority Data
Oct. 30, 2023 (KR) 10-2023-0146493

(51) Int. Cl. H10B 12/00

(52) U.S. Cl. CPC H10B 12/30; H10B 12/05

(57) ABSTRACT

A semiconductor device includes gate electrodes extending in a first horizontal direction on a memory cell region and stacked and spaced apart from each other in a vertical direction, back-gate electrodes extending between the gate electrodes in the first horizontal direction and stacked and spaced apart from each other in the vertical direction, vertical conductive patterns extending in the vertical direction and spaced apart from each other in the first horizontal direction on the memory cell region, active layers between the gate electrodes and the back-gate electrodes, extending in a second horizontal direction intersecting with the first horizontal direction, and electrically connected to the vertical conductive patterns on the memory cell region, and a through-plug extending in the vertical direction and in contact with side surfaces of the back-gate electrodes.

### CROSS-REFERENCE TO RELATED APPLICATION(S)

This application claims benefit of priority to Korean Patent Application No. 10-2023-0146493 filed on Oct. 30, 2023 in the Korean Intellectual Property Office, the disclosure of which is incorporated herein by reference in its entirety.

### BACKGROUND

Example embodiments of the present disclosure relate to semiconductor devices including a through-plug.

As demand for high performance, high speed, and/or multifunctionality of a semiconductor device have increased, integration density of a semiconductor device has increased. In manufacturing a fine-patterned semiconductor device in response to the trend for high integration density of a semiconductor device, it may be necessary to implement patterns having a fine width or a fine spacing.

### SUMMARY

Some example embodiments of the present disclosure provide semiconductor devices including a through-plug.

According to an example embodiment of the present disclosure, a semiconductor device includes a substrate including a memory cell region, a contact region and an interface region between the memory cell region and the contact region, gate electrodes extending in a first horizontal direction on the memory cell region and stacked and spaced apart from each other in a vertical direction, back-gate electrodes extending between the gate electrodes in the first horizontal direction and stacked and spaced apart from each other in the vertical direction, vertical conductive patterns extending in the vertical direction and spaced apart from each other in the first horizontal direction on the memory cell region, active layers between the gate electrodes and the back-gate electrodes, the active layers extending in a second horizontal direction intersecting with the first horizontal direction, the active layers electrically connected to the vertical conductive patterns on the memory cell region, and a through-plug extending in the vertical direction and in contact with side surfaces of the back-gate electrodes.

According to an example embodiment of the present disclosure, a semiconductor device includes a substrate including a memory cell region, a contact region and an interface region between the memory cell region and the contact region, stack structures extending in a first horizontal direction and spaced apart from each other in a second horizontal direction intersecting with the first horizontal direction, the stack structures including first stack structures on the memory cell region and second stack structures on the interface region, and the contact region, the second stack structure electrically connected to the first stack structures, and through-plugs penetrating the stack structures in a vertical direction, wherein the first stack structures include gate electrodes extending in the first horizontal direction and stacked and spaced apart from each other in the vertical direction, back-gate electrodes extending in the first horizontal direction between the gate electrodes and stacked and spaced apart from each other in the vertical direction, and active layers between the gate electrodes and the back-gate electrodes, the active layers including channel regions extending in the second horizontal direction and overlapping the gate electrodes in the vertical direction, and wherein the through-plugs are electrically connected to the back-gate electrodes.

According to an example embodiment of the present disclosure, a semiconductor device includes a substrate including a memory cell region, a contact region and an interface region between the memory cell region and the contact region, gate electrodes extending in a first horizontal direction on the memory cell region and stacked and spaced apart from each other in a vertical direction, back-gate electrodes extending in the first horizontal direction between the gate electrodes and stacked and spaced apart from each other in the vertical direction, vertical conductive patterns extending in the vertical direction and arranged and spaced apart from each other in the first horizontal direction on the memory cell region, active layers between the gate electrodes and the back-gate electrodes, the active layers extending in a second horizontal direction intersecting with the first horizontal direction, the active layers electrically connected to the vertical conductive patterns on the memory cell region, a capacitor structure electrically connected to the active layers, a through-plug extending in the vertical direction and in contact with side surfaces of the back-gate electrodes, and contact plugs on the contact region and electrically connected to the gate electrodes, wherein the through-plug is offset from an axis of a corresponding one of the gate electrodes running in the first horizontal direction by connecting center points thereof in the second horizontal direction, on the memory cell region, and wherein the through-plug has a first horizontal width at a same level as a level of the gate electrodes and a second horizontal width greater than the first horizontal width at a same level as a level of the back-gate electrodes.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a circuit diagram illustrating a memory cell array of a semiconductor device according to an example embodiment of the present disclosure;

FIG. 2 is a plan view illustrating a semiconductor device according to an example embodiment of the present disclosure;

FIGS. 3A to 6 are vertical cross-sectional diagrams illustrating a semiconductor device according to an example embodiment of the present disclosure;

FIG. 7 is a plan view illustrating a semiconductor device according to an example embodiment of the present disclosure;

FIG. 8A is a plan view illustrating a semiconductor device according to an example embodiment of the present disclosure;

FIGS. 8B is a vertical cross-sectional diagram illustrating a semiconductor device according to an example embodiment of the present disclosure;

FIGS. 9 to 12 are plan views illustrating a semiconductor device according to some example embodiments of the present disclosure;

FIG. 13 is a vertical cross-sectional diagram illustrating a semiconductor device according to an example embodiment of the present disclosure;

FIGS. 14A and 14B are vertical cross-sectional diagrams illustrating a semiconductor device according to some example embodiments of the present disclosure;

FIGS. 15 to 35 are cross-sectional diagrams illustrating a method of manufacturing a semiconductor device according to an example embodiment of the present disclosure; and

FIGS. 36 to 41 are cross-sectional diagrams illustrating a method of manufacturing a semiconductor device according to an example embodiment of the present disclosure.

### DETAILED DESCRIPTION

Hereinafter, some example embodiments in the example embodiment will be described as follows with reference to the accompanying drawings.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

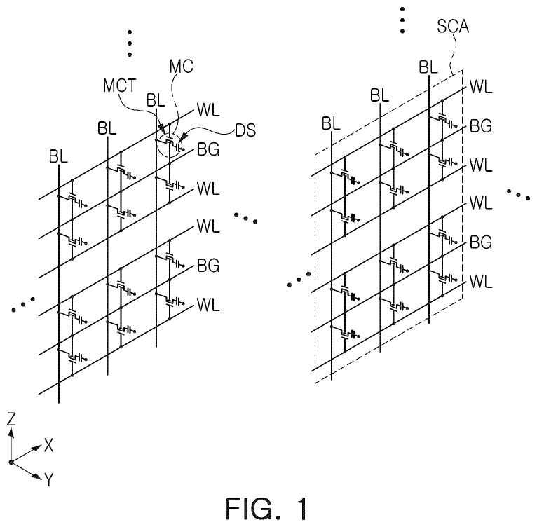

FIG. 1 is a circuit diagram illustrating a memory cell array of a semiconductor device according to an example embodiment.

Referring to FIG. 1, a memory cell array of a semiconductor device according to an example embodiment may include a plurality of sub-cell arrays SCA. The plurality of sub-cell arrays SCA may be arranged in the Y-direction. Each of the plurality of sub-cell arrays SCA may include a plurality of bitlines BL, a plurality of wordlines WL, a plurality of back-gate lines BG, and a plurality of memory cells MC. The memory cell MC may include a memory cell transistor MCT and a data storage element DS. A memory cell MC may be disposed between a wordline WL and a bitline BL. A cell array of a semiconductor device may correspond to the memory cell array of a dynamic random access memory (DRAM) device.

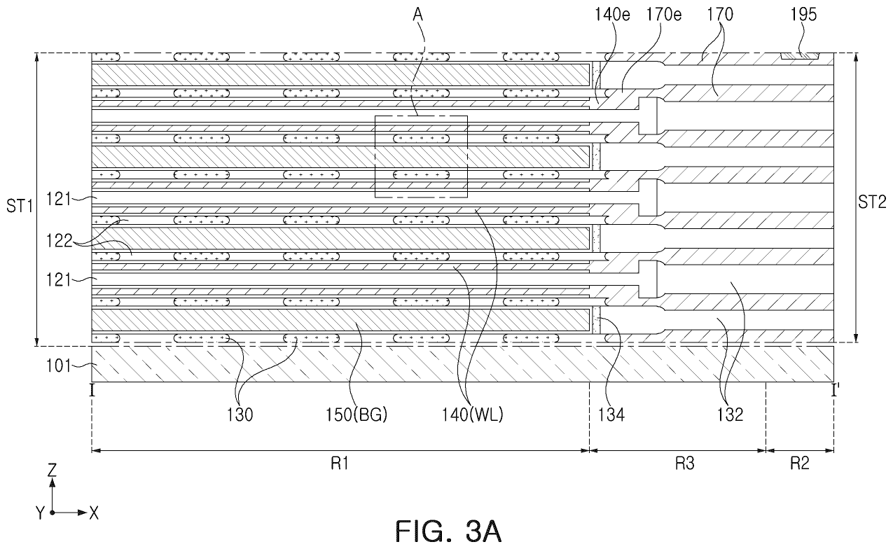

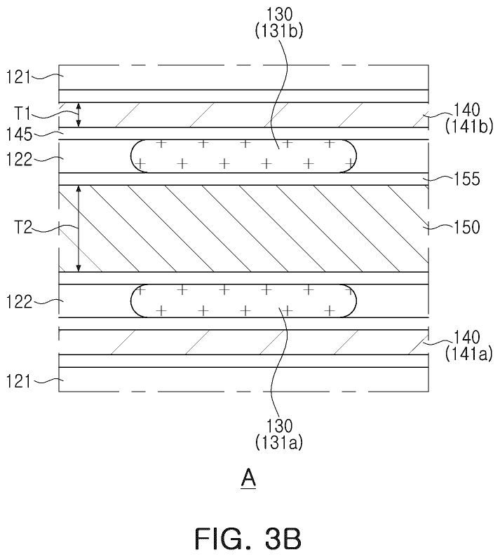

The wordlines WL may extend in the X-direction. The wordlines WL in a sub-cell array SCA may be spaced apart from each other in the Z-direction. The bitlines BL may extend in the Z-direction. The bitlines BL in a sub-cell array SCA may be spaced apart from each other in the X-direction. The wordlines WL and the bitlines BL may be disposed on a substrate (101 in FIG. 3A) and may be conductive patterns (e.g., metal lines) extending in one direction. In the present disclosure, the X-direction, the Y-direction and the Z-direction may be referred to as a first horizontal direction, a second horizontal direction and a vertical direction, respectively.

The memory cell transistor MCT may include a gate, a source, and a drain. The gate may be connected to the wordline WL, the source may be connected to the bitline BL, and the drain may be connected to the data storage element DS. The data storage element DS may include a capacitor including lower and upper electrodes and a dielectric layer.

A back-gate line BG may be disposed between two adjacent wordlines WL. For example, two adjacent wordlines WL may share a back-gate line BG. A voltage different from a voltage applied to wordlines WL may be applied to the back-gate line BG. Channel regions (130c in FIG. 3A), which are channels of the memory cell transistor MCT, may be floating bodies, and the back-gate line BG may control charges (e.g., holes) accumulated in the channel regions (130c in FIG. 3A) such that the back-gate line BG may suppress or control a floating body effect, and may mitigate or prevent a threshold voltage of the memory cell transistors MCT from changing. Accordingly, the back-gate line BG may improve electrical properties of the memory cell transistors MCT.

In an example, the back-gate lines BG may be controlled independently and individually in consideration of distribution of properties of the memory cell transistors MCT disposed on each layer. In some example embodiments, at least some of the back-gate lines BG may be electrically connected to each other and may be controlled together.

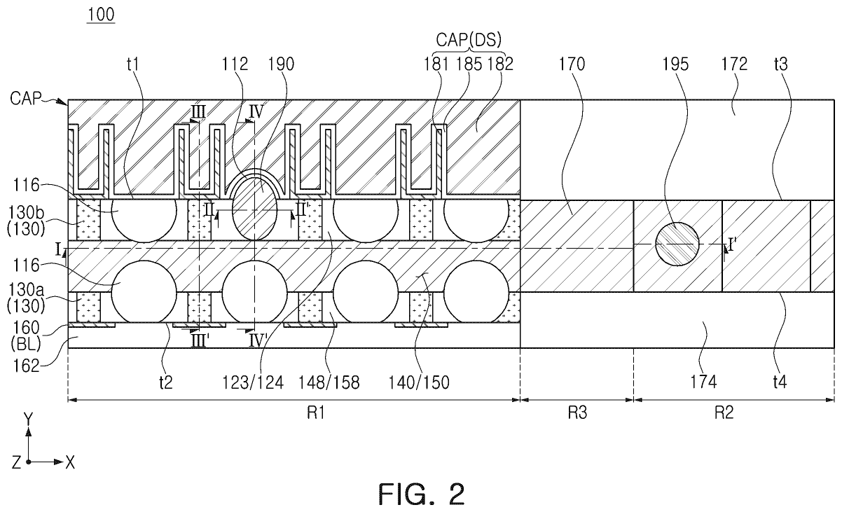

According to an example embodiment, the circuit diagram in FIG. 1 may be implemented, for example, with a semiconductor device described with reference to FIGS. 2 to 6 below.

FIG. 2 is a plan view illustrating a semiconductor device according to an example embodiment, illustrating a structure of sub-cell array described with reference to FIG. 1.

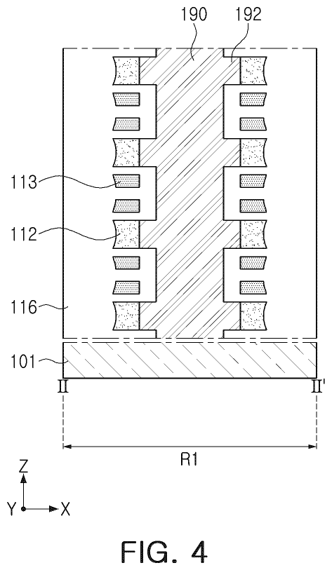

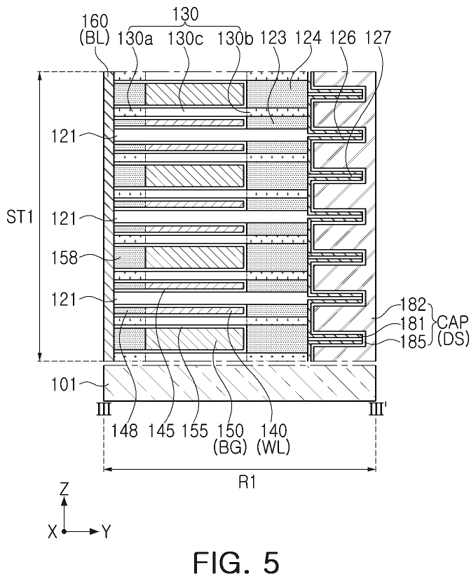

FIGS. 3A to 6 are vertical cross-sectional diagrams illustrating a semiconductor device according to an example embodiment. FIG. 3A is a vertical cross-sectional diagram illustrating the semiconductor device in FIG. 2 taken along line I-I′. FIG. 3B is an enlarged diagram illustrating region A in FIG. 3A. FIG. 4 is a cross-sectional diagram illustrating the semiconductor device in FIG. 2 taken along line II-II′. FIG. 5 is a vertical cross-sectional diagram illustrating a semiconductor device taken along line III-III′.

Referring to FIGS. 2 to 5, a semiconductor device 100 may include a substrate 101, stack structures ST1 and ST2 on the substrate 101, vertical conductive patterns 160 extending in the Z-direction, a capacitor structure CAP, a through-plug 190 and contact plugs 195.

The substrate 101 may include a semiconductor material, such as a group IV semiconductor, a group III-V compound semiconductor, or a group II-VI compound semiconductor. For example, a group IV semiconductor may include silicon, germanium, or silicon-germanium. The substrate 101 may further include impurities. The substrate 101 may be a silicon substrate, a silicon on insulator (SOI) substrate, a germanium substrate, a germanium on insulator (GOI) substrate, a silicon-germanium substrate, or a substrate including an epitaxial layer.

The substrate 101 may include a memory cell region R1, a contact region R2, and an interface region R3. The interface region R3 may be disposed between a memory cell region R1 and a contact region R2.

The stack structures ST1 and ST2 may include a first stack structure ST1 disposed on the memory cell region R1 and a second stack structure ST2 disposed on the contact region R2 and the interface region R3. The first stack structure ST1 may include active layers 130 extending in the Y-direction, a gate structure (alternatively, referred to as a “gate electrode”) 140 intersecting with active layers 130 and extending in the X-direction, gate dielectrics 145 and 155, capping insulating layers 123 and 124, gate capping layers 148 and 158, isolating insulating layers 126 and 127, first interlayer insulating layers 121 and second interlayer insulating layers 122.

The capacitor structure CAP may include a first electrode 181, a second electrode 182, and a capacitor dielectric 185 between the first and second electrodes 181 and 182. The capacitor structure CAP may provide a plurality of data storage elements DS. The X-direction and Y-direction may be directions parallel to an upper surface of the substrate 101, respectively, and the Z-direction may be a direction perpendicular to an upper surface of the substrate 101.

The semiconductor device 100 may include, for example, a DRAM cell array. The vertical conductive pattern 160 may correspond to the bitline BL in FIG. 1, the gate electrode 140 may correspond to the wordline WL in FIG. 1, a back-gate electrode (alternatively, referred to as “back-gate structure”) 150 may correspond to the back-gate line BG in FIG. 1, and the capacitor structure CAP may correspond to the data storage element DS in FIG. 1.

The active layers 130 may be disposed on the substrate 101 and may extend horizontally in the Y-direction. The active layers 130 may be spaced apart from each other in the X-direction and the Z-direction. The second interlayer insulating layers 122 may be disposed between the active layers 130 arranged in the X-direction. The active layers 130 may intersect with the gate structures (alternatively, referred to as “gate electrodes”) 140 and 150 and may have a line shape, a bar shape, or a pillar shape extending in the Y-direction. In an example, the active layers 130 may include a semiconductor material, such as silicon, germanium, or silicon-germanium. The second interlayer insulating layer 122 may include at least one of silicon oxide, silicon nitride, silicon oxynitride, or silicon oxycarbide, and may include, for example, silicon oxide.

Each of the active layers 130 may include a first region 130a, a second region 130b, and a channel region 130c. The channel region 130c may be disposed between the first region 130a and the second region 130b. The first region 130a may be in contact with the vertical conductive pattern 160 and may be electrically connected to the vertical conductive pattern 160. The second region 130b may be in contact with the first electrode 181 of the capacitor structure CAP and may be electrically connected to the first electrode 181. A length of the first region 130a in the Y-direction and a length of the second region 130b in the Y-direction may be different from each other or may be the same. The channel region 130c may overlap the gate structures 140 and 150 in the Z-direction. When the active layer 130 includes or is formed of a semiconductor material, each of the first region 130a and the second region 130b may include impurities, and the impurities may have N-type conductivity or P-type conductivity.

At least a portion of the first region 130a may correspond to the first source/drain region of the memory cell transistor MCT in FIG. 1, and at least a portion of the second region 130b may correspond to the second source/drain region of the memory cell transistor MCT in FIG. 1. At least a portion of channel region 130c may correspond to a channel of the memory cell transistor MCT in FIG. 1. The first region 130a may provide a region for directly connecting the memory cell transistor MCT to the bitline BL, and the second region 130b may provide a region for directly connecting the memory cell transistor MCT to the data storage element DS.

In some example embodiments, the active layers 130 may include at least one of an oxide semiconductor, such as hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO), and indium-tin-zinc oxide (ITZO).

In some other example embodiments, the active layers 130 may include a two-dimensional material (2D material) in which atoms may form a desired (or alternatively, predetermined) crystal structure and may form a channel of a transistor. The two-dimensional material layer may include at least one of a transition metal dichalcogenide (TMD) material layer, a black phosphorous material layer, or a hexagonal boron-nitride material layer (hBN material layer). For example, the two-dimensional material layer may include at least one of BiOSe, Crl, WSe2, MoS2, TaS, WS, SnSe, ReS, β-SnTe, MnO, AsS, P(black), InSe, h-BN, GaSe, GaN, SrTiO, MXene, or Janus 2D materials.

In some example embodiments, the first stack structure ST1 may further include epitaxial layers grown from the active layer 130 and connected to the first region 130a and the second region 130b of the active layer 130, respectively.

The semiconductor device 100 may further include insulating pillars 116 disposed between the active layers 130 spaced apart from each other in the X-direction. The insulating pillars 116 may be spaced apart from each other in the X-direction and the Y-direction. In a plan view, the insulating pillars 116 may be spaced apart from each other in the X-direction with the active layers 130 therebetween, and may be spaced apart from each other in the Y- direction with the gate structures 140 and 150 therebetween.

The first interlayer insulating layer 121 may be disposed between gate electrodes (alternatively referred to as “gate structures”) 140 adjacent to each other in the Z-direction and may extend in the horizontal direction. The first interlayer insulating layer 121 may further extend to the interface region R3. The first interlayer insulating layer 121 may include at least one of silicon oxide, silicon nitride, silicon oxynitride, or silicon oxycarbide, and may include, for example, silicon oxide.

The gate electrodes 140 may be disposed on the substrate 101 and may extend horizontally in the X-direction. The gate electrodes 140 may be spaced apart from each other in the Y-direction and the Z-direction. The gate electrodes 140 may be disposed between the channel region 130c of the active layer 130 and the first interlayer insulating layer 121. The gate electrodes 140 may intersect with the vertical conductive pattern 160 and may have a line shape, a bar shape, or a pillar shape extending in the X-direction.

The gate electrodes 140 may include a conductive material, and the conductive material may be a doped semiconductor material (e.g., doped silicon, doped germanium, or the like), a conductive metal nitride (e.g., titanium nitride, tantalum nitride, tungsten, or the like) metal (e.g., tungsten, titanium, tantalum, cobalt, aluminum, ruthenium, or the like), or a metal-semiconductor compound (e.g., tungsten silicide, cobalt silicide, titanium silicide, or the like). The gate electrodes 140 may be wordlines WL described with reference to FIG. 1.

The back-gate electrodes (alternatively referred to as “back-gate structures”) 150 may be disposed between the gate electrodes 140. For example, a back-gate electrode 150 may be disposed between at least two gate electrodes 140. The back-gate electrodes 150 may be spaced apart from each other in the Y-direction and the Z-direction. Each back-gate electrode 150 may be disposed between the channel regions 130c of two active layers 130 adjacent to each other in the Z-direction. The back-gate electrodes 150 may have a line shape, a bar shape, or a pillar shape extending in the X-direction.

The back-gate electrodes 150 may include a conductive material, for example, the same material as that of the gate electrodes 140.

Referring to FIG. 3B, the back-gate electrode 150 may be disposed between the first gate electrode 141a and the second gate electrode 141b, which are spaced apart from each other in the Z-direction. Among the active layers 130, a first active layer 131a may be disposed between the first gate electrode 141a and the back-gate electrode 150, and a second active layer 131b may be disposed between the second gate electrode 141b and the back-gate electrode 150. In an example, a vertical thickness T2 of the back-gate electrode 150 may be different from a vertical thickness T1 of the first gate electrode 141a and the second gate electrode 141b. For example, the vertical thickness T2 of the back-gate electrode 150 may be different from the vertical thickness T1 of the first gate electrode 141a and the second gate electrode 141b, and the vertical thickness T2 of the back-gate electrode 150 may be greater than the vertical thickness T1 of the first gate electrode 141a and the second gate electrode 141b.

Referring to FIG. 3A, the gate electrodes 140 may extend further in the X-direction than the back-gate electrodes 150. For example, the back-gate electrodes 150 may be disposed on the memory cell region R1, and the gate electrodes 140 may further extend to the interface region R3. Ends 140e of the gate electrodes 140 may be connected to connection pads 170 on the interface region R3.

According to an example embodiment, a back-gate line BG shared by two wordlines WL may be provided by disposing a back-gate electrode 150 between two gate electrodes 140.

A voltage may be applied to the channel regions 130c of the active layers 130 adjacent to the back-gate electrode 150 through the back-gate electrode 150, thereby controlling a threshold voltage of the memory cell transistor MCT and/or suppressing a floating body effect. Accordingly, electrical properties and reliability of the semiconductor device may be improved.

The gate dielectrics 145 and 155 may include gate dielectric layers 145 covering upper/lower surfaces of each of the gate electrodes 140 and back-gate dielectric layers 155 covering upper/lower surfaces of each of the back-gate electrodes 150.

The gate dielectric layer 145 may be disposed between the gate electrode 140 and the active layer 130, between the gate electrode 140 and the second interlayer insulating layer 122, and between the gate electrode 140 and the capping insulating layer 123. The gate dielectric layer 145 may be in contact with the vertical conductive pattern 160. The gate dielectric layer 145 may include at least one of silicon oxide, silicon nitride, a low-K material, or a high-K material. The high-k material may refer to a dielectric material having a dielectric constant higher than that of silicon oxide, and the low-material may refer to a dielectric material having a dielectric constant lower than that of silicon oxide. The high-K material may be, for example, metal oxide or metal oxynitride. The high-K material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSixOy), hafnium oxide (HfO₂), hafnium silicon oxide (HfSixOy), lanthanum oxide (La₂O₃), lanthanum aluminum oxide (LaAlxOy), lanthanum hafnium oxide (LaHfxOy), hafnium aluminum oxide (LaAlxOy), or praseodymium oxide (Pr₂O₃). The gate dielectric layer 145 may be formed as a single layer or multiple layers of the above-described materials.

The back-gate dielectric layer 155 may be disposed between the back-gate electrode 150 and the active layers 130, and between the back-gate electrode 150 and the capping insulating layer 124. The back-gate dielectric layer 155 may be in contact with the vertical conductive pattern 160. The back-gate dielectric layer 155 may include the same material as that of the gate dielectric layer 145.

The capping layers 123 and 124 may include a capping insulating layer 123 and a capping insulating layer 124. The capping insulating layer 123 may be disposed between the gate electrode 140 and the first electrode 181 of the capacitor structure CAP. The second capping insulating layer 124 may be disposed between the back-gate electrode 150 and the first electrode 181 of the capacitor structure CAP. The capping layers 123 and 124 may include a material different from that of the first interlayer insulating layers 121. The capping layers 123 and 124 may include at least one of insulating material, for example, silicon nitride, silicon oxynitride, or silicon oxycarbide. The capping layers 123 and 124 may overlap the second region 130b of the active layer 130 in the Z-direction.

The gate capping layers 148 and 158 may include a gate capping layer 148 and a back-gate capping layer 158. The gate capping layer 148 may be disposed between the gate electrode 140 and the vertical conductive pattern 160. Upper/lower surfaces of the gate capping layer 148 may be covered by the gate dielectric layer 145. The back-gate capping layer 158 may be disposed between the back-gate electrode 150 and the vertical conductive pattern 160. Upper/lower surfaces of the back-gate capping layer 158 may be covered by the back-gate dielectric layer 155. The capping layers 148 and 158 may include a material different from that of the first interlayer insulating layers 121. The capping layers 148 and 158 may include at least one of insulating material, for example, silicon nitride, silicon oxynitride, or silicon oxycarbide. The capping layers 148 and 158 may overlap the first region 130a of the active layer 130 in the Z-direction.

The isolating insulating layers 126 and 127 may be disposed between the first electrodes 181 and may include first isolating insulating layers 126 and second isolating insulating layers 127 stacked alternately. The first isolating insulating layer 126 may extend in the Y-direction from the second interlayer insulating layer 122 and may have a thickness smaller than a thickness of the second interlayer insulating layer 122. The second isolating insulating layer 127 may be connected to the capping insulating layer 124 and may have a thickness smaller than a thickness of the capping insulating layer 124. The isolating insulating layers 126 and 127 may include an insulating material, for example, silicon oxide.

The second interlayer insulating layers 122 may be disposed to be in contact with side surfaces of the active layers 130 between the gate electrodes 140 disposed at the same level and between the back-gate electrodes 150 disposed at the same level. The second interlayer insulating layer 122 may have a thickness less than a thickness of the first interlayer insulating layer 121, but an example embodiments are not limited thereto. The second interlayer insulating layers 122 may include an insulating material (e.g., at least one of silicon oxide, silicon nitride, silicon oxynitride, or silicon oxycarbide).

The vertical conductive patterns 160 may extend vertically in the Z-direction on the substrate 101. The vertical conductive patterns 160 may be spaced apart from each other in the X-direction. The plurality of active layers 130 stacked in the Z-direction may be electrically connected to a vertical conductive pattern 160. For example, the vertical conductive pattern 160 may be electrically connected to the first regions 130a. The vertical conductive patterns 160 may have a line shape, a bar shape, or a pillar shape extending in the Z-direction. The vertical conductive patterns 160 may include at least one of a doped semiconductor material, conductive metal nitride, metal, or a metal-semiconductor compound. The vertical conductive patterns 160 may correspond to the bitline BL described with reference to FIG. 1.

The semiconductor device 100 may further include an insulating structure 162 covering a side surface of the vertical conductive patterns 160. The insulating structure 162 may be disposed in the second trench T2 illustrated in FIG. 2 and may extend in the X-direction.

The second stack structure ST2 may further include connection pads 170 and connection insulating layers 132. For example, the connection pads 170 and the connection insulating layers 132 may be stacked alternately. In an example embodiment, a portion of the first interlayer insulating layer 121 may be disposed between the connection pads 170. The connection pad 170 may be connected to the gate electrode 140 and the interface region R3. For example, an end 140e of the gate electrode 140 may be in contact with an end 170e of the connection pad 170 and the ends may be integrated with each other. In an example embodiment, each gate electrode 140 may be disposed at a level different from a level of the connection pad 170 connected thereto. The structure of the gate electrode 140 and the connection pad 170 illustrated in FIG. 3A is merely an example, and example embodiments are not limited thereto. In an example embodiment, the connection pads 170 spaced apart from each other in the Z-direction may have different lengths extending in the X-direction. For example, the connection pads 170 may have a staircase structure.

The semiconductor device 100 may further include a first gap-fill insulating pattern 172 and a second gap-fill insulating pattern 174 disposed in the contact region R2 and the interface region R3. The first gap-fill insulating pattern 172 may fill the third trench t3 and may extend in the X-direction. The first gap-fill insulating pattern 172 may be in contact with the capacitor structure CAP. The second gap-fill insulating pattern 174 may fill the fourth trench t4 and may extend in the X-direction. The second gap-fill insulating pattern 174 may be in contact with the insulating structure 162. The first gap-fill insulating pattern 172 and the second gap-fill insulating pattern 174 may be spaced apart from each other in the Y-direction with the connection pads 170 therebetween.

The capacitor structure CAP may be disposed in the first trench T1 illustrated in FIG. 2 and may extend in the X-direction. The capacitor structure CAP may be disposed adjacent to the second region 130b of the active layer 130. The capacitor structure CAP may be electrically connected to the second region 130b of the active layer 130. The capacitor structure CAP may include a first electrode 181, a capacitor dielectric 185 on the first electrode 181, and a second electrode 182 on the capacitor dielectric 185. As illustrated in FIGS. 2 and 3A, the first electrode 181 may have a cylindrical shape, but in example embodiments are not limited thereto, and, in example embodiments, the first electrode 181 may have a pillar shape.

The first electrodes 181 may be in a state in which nodes thereof may be separated from each other by the isolating insulating layers 126 and 127. The first electrodes 181 may be referred to as “storage node electrodes.” The first electrodes 181 may include at least one of a doped semiconductor material, a conductive metal nitride, a metal, and a metal-semiconductor compound.

The capacitor dielectric 185 may conformally cover the first electrode 181. For example, the capacitor dielectric 185 may include a high-k material (e.g., at least one of zirconium oxide (ZrO₂), aluminum oxide (Al₂O₃), or hafnium oxide (Hf₂O₃)).

The second electrode 182 may cover the capacitor dielectric 185 and may extend in the X-direction. The second electrode 182 may be referred to as a “plate electrode.” The second electrode 182 may include at least one of a doped semiconductor material, conductive metal nitride, metal, or a metal-semiconductor compound.

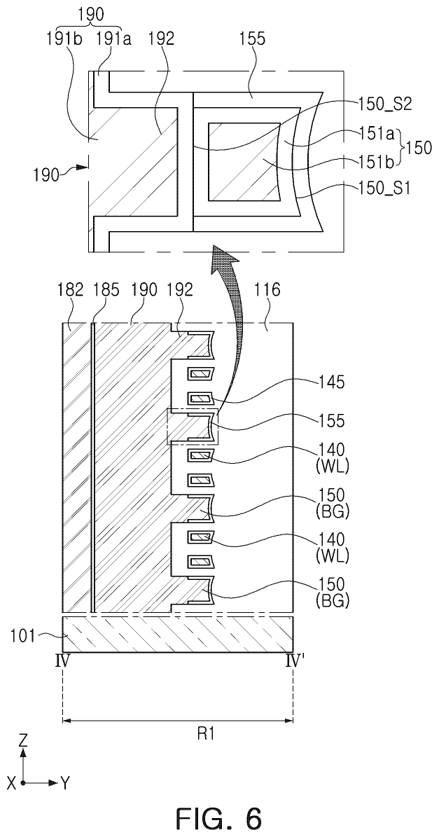

FIG. 6 illustrates a vertical cross-sectional diagram along the line IV-IV′ of the semiconductor device in FIG. 2.

Referring to FIGS. 2, 4 and 6, in an example embodiment, a through-plug 190 may be disposed on the memory cell region R1. For example, the through-plug 190 may be disposed between the gate structures 140 and 150 and the capacitor structure CAP. In an example embodiment, a portion of the through-plug 190 may be disposed in the first trench T1 and may overlap the capacitor structure CAP in the X-direction. In some example embodiments, the through-plug 190 may be spaced apart from the capacitor structure CAP and may overlap the gate structures 140 and 150 in the Z-direction.

The through-plug 190 may be in contact with a plurality of back-gate electrodes 150 that are spaced apart from each other in the Z-direction. The through-plug 190 may penetrate through the first stack structure ST1, may extend in the Z-direction and may electrically connect the plurality of back-gate electrodes 150 to each other. Because the plurality of back-gate electrodes 150 may be connected to each other by a through-plug 190 (instead of providing a plurality of plugs corresponding to the back-gate electrodes 150, respectively), a size of the semiconductor device 100 may be reduced. Furthermore, because the through-plug 190 is not aligned with axis of the gate structures 140 and 150 in the X-direction and is disposed to be shifted from the corresponding gate structures 140 and 150, an area in which the through-plug 190 and the gate structures 140 and 150 overlap in the Z-direction may be reduced. Accordingly, resistance of the gate structures 140 and 150 may be not excessively increased or may be prevented from excessively increasing by the through-plug 190.

The through-plug 190 may have a first horizontal width at the same level as a level of the gate electrodes 140, and may have a second horizontal width greater than the first horizontal width at the same level as a level of the back-gate electrodes 150. In an example embodiment, the through-plug 190 may include protrusions 192 protruding in the horizontal direction from a side surface of the through-plug 190. For example, the protrusions 192 may extend along the periphery of the through-plug 190. Each of the protrusions 192 may be connected to a corresponding back-gate electrode 150. For example, the back-gate electrode 150 may include a first side surface 150_S1 covered by the back-gate dielectric layer 155 and a second side surface 150_S2 not covered by the back-gate dielectric layer 155 and in contact with the protrusion 192. In an example embodiment, the through-plug 190 may include a barrier layer 191a and a conductive layer 191b on the barrier layer 191a, and the back-gate electrode 150 may include a barrier layer 151a and a conductive layer 151b on the barrier layer 151a. The barrier layer 151a of the back-gate electrode 150 may be in contact with the barrier layer 191a of the through-plug 190 at the second side surface 150_S2, and may be in contact with the back-gate dielectric layer 155 at an upper surface, a lower surface and the first side surface 150_S1 of the back-gate electrode 150. The barrier layer 151a and the barrier layer 191a may include conductive nitride, and the conductive layer 151b and the conductive layer 191b may include a metal material.

The semiconductor device 100 may further include isolating insulating layers 112 and capping layers 113. The isolating insulating layers 112 may be disposed at the same level as a level of the back-gate electrodes 150, and a portion of the protrusions 192 of the through-plug 190 may be in contact with the isolating insulating layers 112. For example, the protrusions 192 extending along the periphery of the through-plug 190 may be in contact with both the isolating insulating layers 112 and the back-gate electrode 150. As illustrated in FIG. 2, in a plan view, the isolating insulating layers 112 may be disposed between the through-plug 190 and the capacitor structure CAP. For example, the isolating insulating layers 112 may extend along a side surface of the through-plug 190 and may be covered by the capacitor dielectric 185. Although not illustrated, the isolating insulating layers 112 may further extend along a side surface of a portion of the through-plug 190 not overlapping the capacitor structure CAP in the X-direction.

The capping layers 113 may be provided as a pair between the isolating insulating layers 112 and may be spaced apart from each other in the Z-direction. For example, the capping layers 113 may be disposed at the same level as a level of gate electrodes 140. The capping layers 113 may be surrounded by the insulating pillar 116.

In an example embodiment, the semiconductor device 100 may further include insulating layers 134 in contact with the back-gate dielectric layer 155 on the interface region R3.

Contact plugs 195 may be disposed on the contact region R2. For example, the connection pads 170 may be disposed as a staircase structure, and the contact plugs 195 may extend in the Z-direction and may be in contact with an end of the corresponding connection pad 170. The contact plugs 195 may be electrically connected to the gate electrodes 140 through the connection pads 170. The contact plugs 195 may include a conductive material (e.g., at least one of a doped semiconductor material, conductive metal nitride, metal, or a metal-semiconductor compound).

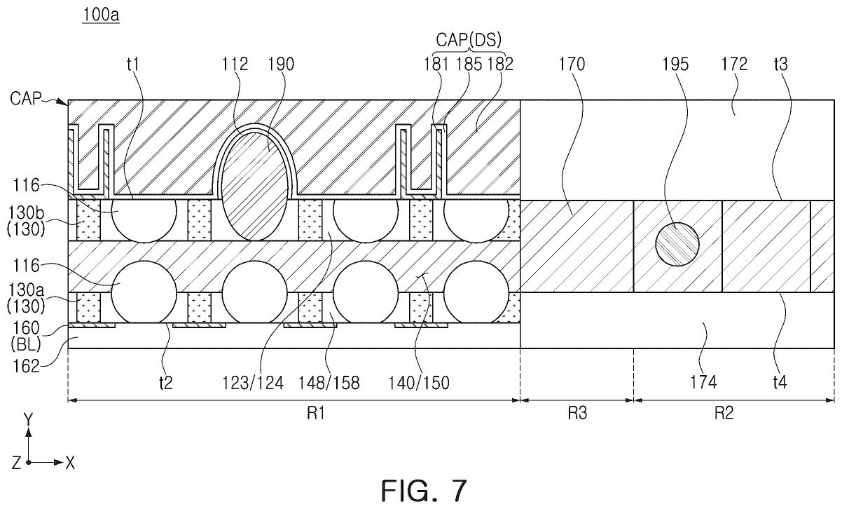

FIG. 7 is a plan view illustrating a semiconductor device according to an example embodiment.

Referring to FIG. 7, a semiconductor device 100a may include a through-plug 190 disposed on a memory cell region R1 and in contact with the back-gate electrode 150. In an example embodiment, a portion of the through-plug 190 may be disposed in the first trench T1 and may overlap the capacitor structure CAP in the X-direction. In an example embodiment, the active layers 130 adjacent to the through-plug 190 may not be connected to the capacitor structure CAP. For example, the active layers 130 adjacent to the through-plug 190 may be dummy active layers.

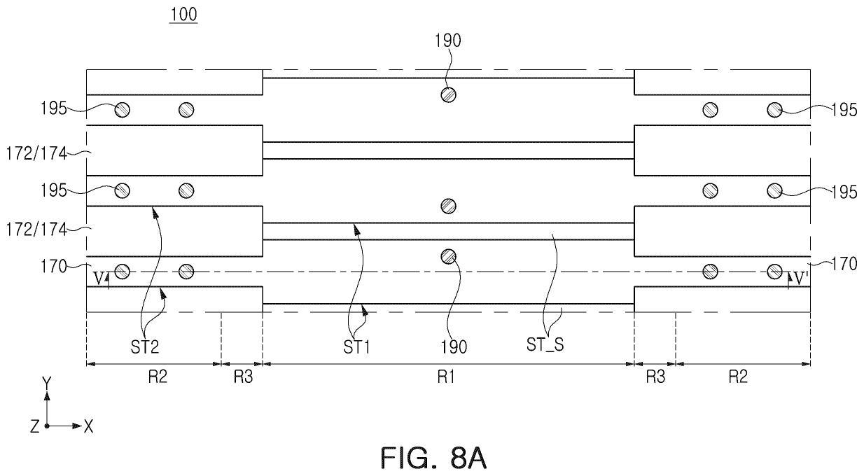

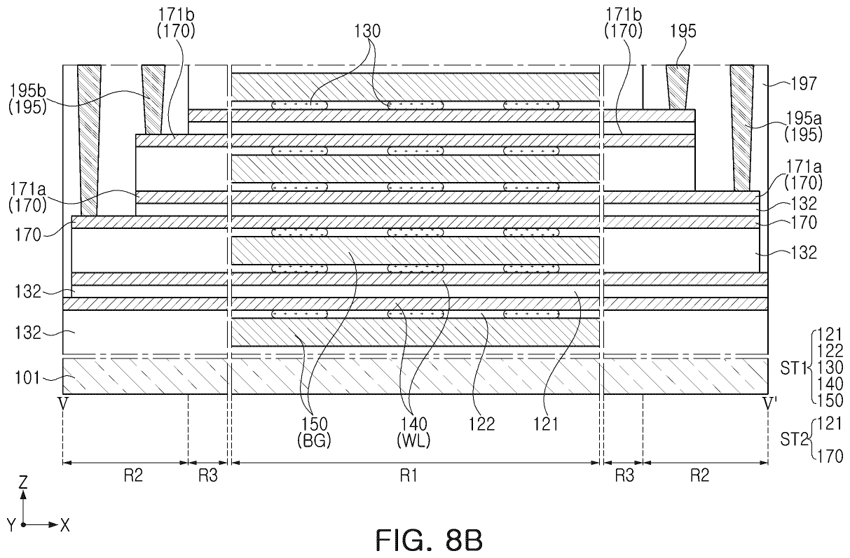

FIG. 8A is a plan view illustrating a semiconductor device according to an example embodiment. FIGS. 8B is a vertical cross-sectional diagram illustrating the semiconductor device of FIG. 8A taken along line V-V′, according to an example embodiment. For ease of description, active layers 130, gate structure 140/150, connection pads 170 and insulating layers therebetween are illustrated.

Referring to FIGS. 8A and 8B, a semiconductor device 100 may include a memory cell region R1, contact regions R2 disposed on both sides of the memory cell region R1, and interface regions R3 between the memory cell region R1 and the contact regions R2. For example, the contact regions R2 may be spaced apart from each other in the X-direction with the memory cell region R1 interposed therebetween.

The semiconductor device 100 may include first stack structures ST1 and second stack structures ST2. The first stack structures ST1 may extend in the X-direction on the memory cell region R1 and may be spaced apart from each other in the Y-direction. The second stack structures ST2 may be disposed on the contact regions R2 and the interface regions R3 and may be disposed on both sides of first stack structures ST1 in the X-direction. The first stack structures ST1 may also be referred to as a cell block.

In an example embodiment, the first stack structure ST1 may have a structure the same as or similar to the first stack structure ST1 described with reference to FIGS. 2 to 6. The second stack structure ST2 may have a structure the same as or similar to the second stack structure ST2 described with reference to FIGS. 2 to 6. The memory cell region R1 may further include isolation layers ST_S between the first stack structures ST1. Each isolation layer ST_S may include a capacitor structure CAP or vertical conductive patterns 160. For example, the isolation layers ST_S including the capacitor structure CAP and isolation layers ST_S including the vertical conductive patterns 160 may be disposed alternately in the Y-direction.

The second stack structures ST2 may be electrically connected to the first stack structures ST1. For example, each of the first stack structures ST1 may be connected to the connection pads 170 extending to the contact regions R2 and the interface regions R3. Gap-fill insulating patterns 172/174 may be disposed between the connection pads 170.

In an example embodiment, the through-plugs 190 may be disposed on the memory cell region R1 and may penetrate through the first stack structures ST1 in the Z-direction. For example, a through-plug 190 may be disposed for each first stack structure ST1, and the through-plug 190 may be in contact with a plurality of back-gate electrodes 150. In an example embodiment, the through-plugs 190 may be disposed so as not to be aligned with X-direction axes of the first stack structures ST1, respectively (e.g., so as to be offset from axes of corresponding ones of the first stack structures ST1 running in the X-direction by connecting center points thereof in the Y-direction, respectively). In an example embodiment, the plurality of through-plugs 190 may be disposed for each first stack structure ST1.

The connection pads 170 may be disposed in a staircase structure on the contact regions R2 and the interface regions R3 and may be covered by an interlayer insulating layer 197. In an example embodiment, the connection pads 170 may be integrated with the gate electrodes 140 and may include a structure or a material the same as or similar to that of the gate electrodes 140. In an example embodiment, the connection pads 170 may be disposed at the same level as a level of the gate electrodes 140.

The contact plugs 195 may be in contact with the connection pads 170 through the interlayer insulating layer 197 on the contact regions R2. For example, the first connection pad 171a and the second connection pad 171b on the first connection pad 171a may be disposed with the back-gate electrode 150 interposed therebetween. The first and second contact regions R2 may be disposed on both sides of the memory cell region R1. The first contact plug 195a in contact with the first connection pad 171a may be disposed in the first contact region R2, and the second contact plug 195b in contact with the second connection pad 171b may be disposed in the second contact region R2.

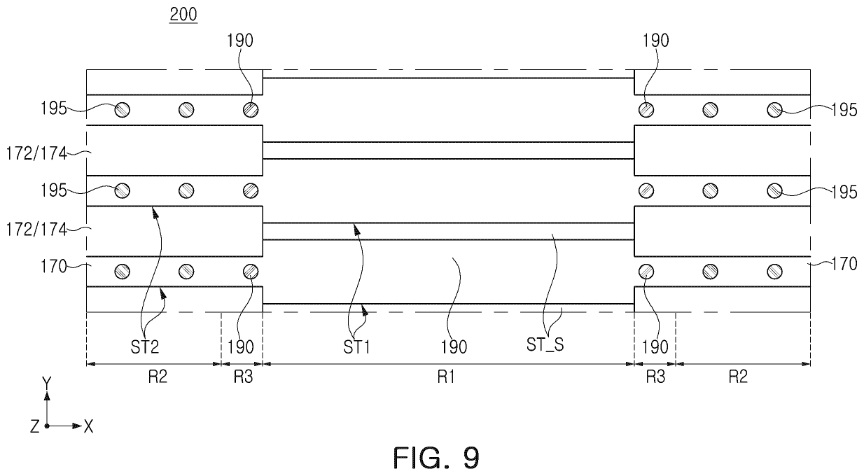

FIGS. 9 to 12 are plan views illustrating a semiconductor device according to some example embodiments.

Referring to FIG. 9, a semiconductor device 200 may include through-plugs 190. In an example embodiment, the through-plugs 190 may be disposed on an interface region R3 and may penetrate through second stack structures ST2 in the Z-direction. Although not illustrated, back-gate electrodes 150 may extend from a memory cell region R1 to the interface region R3 and may be in contact with through-plugs 190. In an example embodiment, the through-plugs 190 may be disposed on both sides of each of first stack structures ST1. The through-plugs 190 may be electrically connected to the first stack structures ST1 and, for example, may be electrically connected to the back-gate electrodes 150 of the first stack structures ST1.

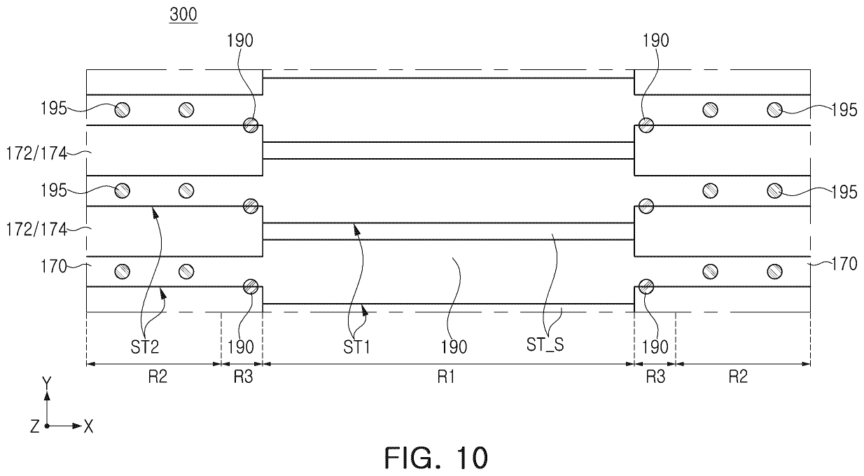

Referring to FIG. 10, a semiconductor device 300 may be disposed on the interface region R3 and may include through-plugs 190 penetrating the second stack structures ST2 in the Z-direction. In an example embodiment, the through-plugs 190 may not be aligned with X-direction axes of the connection pads 170, respectively (e.g., may be offset from axes of corresponding ones of the connection pads 170 running in the X-direction by connecting center points thereof in the Y-direction, respectively). For example, the through-plugs 190 may partially overlap the connection pads 170 in the Z-direction and may be in contact with gap-fill insulating patterns 172/174.

Because the through-plugs 190 are spaced apart from the X-direction axis of the connection pads 170, an overlapping area between the through-plugs 190 and the connection pads 170 in the Z-direction may be reduced. Accordingly, resistance of the connection pads 170 may be not excessively increased or may be prevented from excessively increasing due to the through-plug 190.

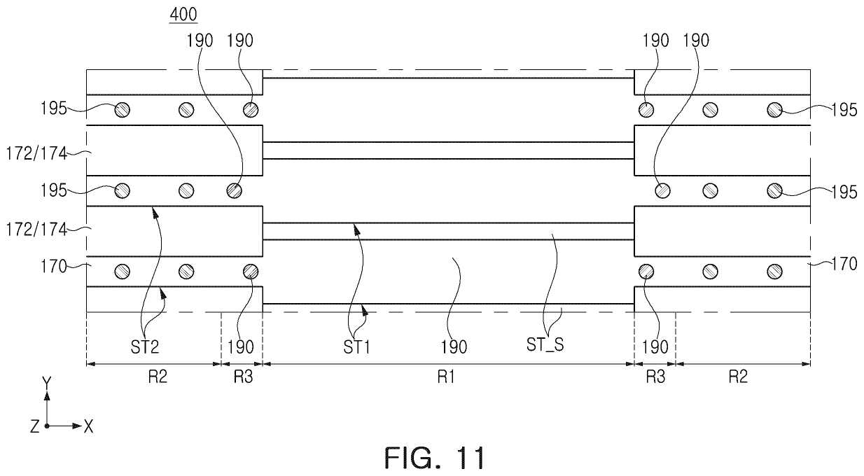

Referring to FIG. 11, a semiconductor device 400 may be disposed on an interface region R3 and may include through-plugs 190 penetrating the second stack structures ST2 in the Z-direction. In an example embodiment, the through-plugs 190 may be disposed in a zigzag pattern in the Y-direction. For example, the through-plugs 190 may be disposed on both sides of each first stack structure ST1, and the through-plugs 190 adjacent to each other in the Y-direction may not be aligned in the X-direction. The through-plugs 190 adjacent to each other in the Y-direction may be spaced apart from each other in the X-direction.

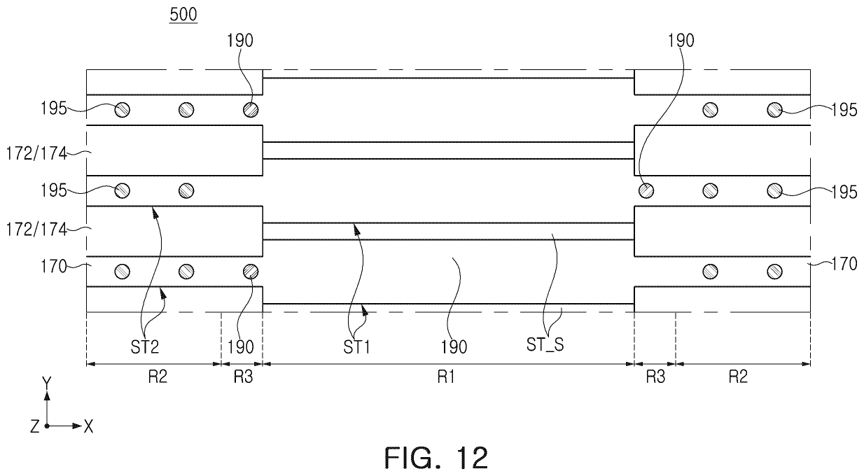

Referring to FIG. 12, the semiconductor device 400 may include through-plugs 190 disposed on the interface region R3 and penetrating the second stack structures ST2 in Z-direction. In an example embodiment, a through-plug 190 may be disposed for each first stack structure ST1, and the through-plugs 190 may be disposed in a zigzag pattern in the Y-direction. For example, the first and second interface regions R3 may be disposed in the X-direction with the memory cell region R1 interposed therebetween, and one of the through-plugs 190 adjacent to each other in the Y-direction may be disposed in the first interface region R3, the other may be disposed in the second interface region R3.

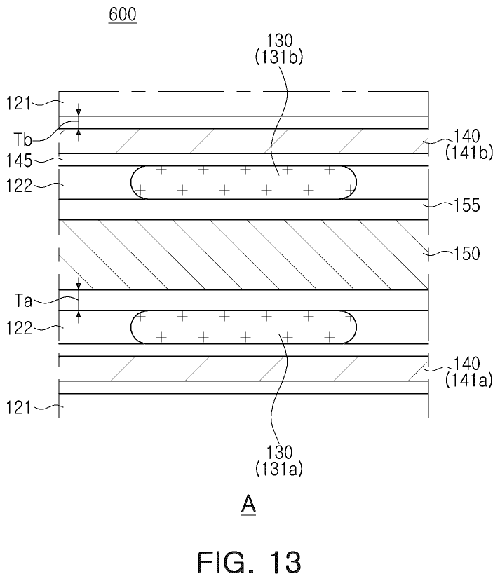

FIG. 13 is a vertical cross-sectional diagram illustrating a semiconductor device according to an example embodiment.

Referring to FIG. 13, a semiconductor device 600 may include a back-gate electrode 150 adjacent to gate electrodes 141a and 141b. The gate electrodes 141a and 141b may be covered by a gate dielectric layer 145, and the back-gate electrode 150 may be covered by a back-gate dielectric layer 155. In an example embodiment, a thickness Ta of the back-gate dielectric layer 155 may be greater than a thickness Tb of the gate dielectric layer 145.

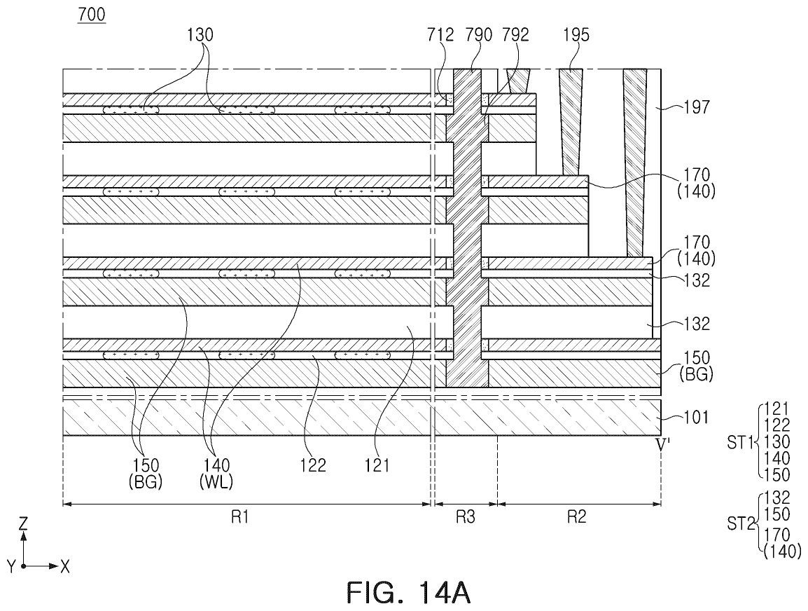

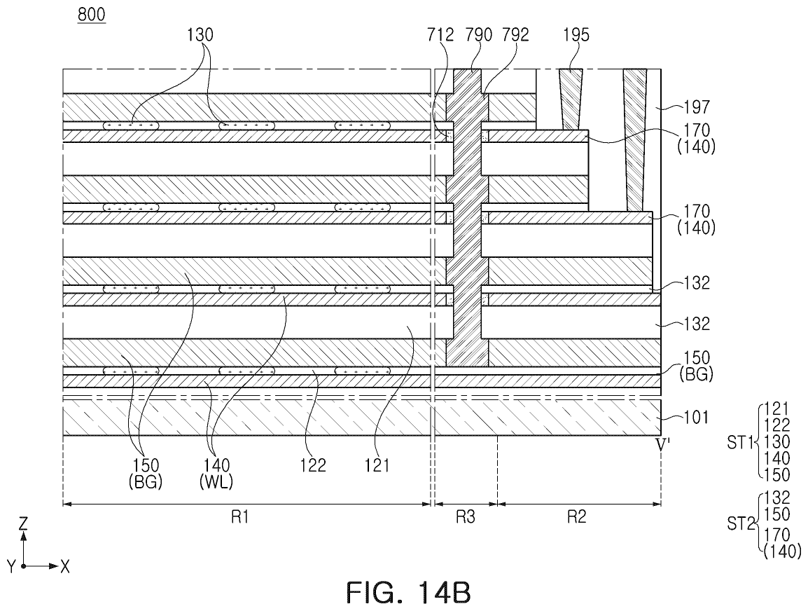

FIGS. 14A and 14B are vertical cross-sectional diagrams illustrating a semiconductor device according to some example embodiments.

Referring to FIG. 14A, a semiconductor device 700 may include a gate electrode 140, a back-gate electrode 150 and a through-plug 790. In an example embodiment, a gate electrode 140 may be disposed to correspond to each back-gate electrode 150. For example, a gate electrode 140 and a back-gate electrode 150 may be disposed as a pair. In an example embodiment, each back-gate electrode 150 may be disposed below a corresponding gate electrode 140. On the memory cell region R1, first interlayer insulating layers 121, second interlayer insulating layers 122, active layers 130, gate electrodes 140 and back-gate electrodes 150 may form a first stack structure ST1.

In an example embodiment, back-gate electrodes 150 may further extend to a contact region R2 and an interface region R3. For example, on the contact region R2, the back-gate electrodes 150 may form a staircase structure together with connection pads 170 and connection insulating layers 132. In an example embodiment, the connection pads 170 may be integrated with the gate electrodes 140. For example, the connection pads 170 may be a portion of the gate electrodes 140 extending to the contact region R2, and may include a structure or a material the same as or similar to that of the gate electrodes 140. Connection insulating layers 132, back-gate electrodes 150 and connection pads 170 on the contact region R2 and the interface region R3 may form a second stack structure ST2. The second stack structure ST2 may be covered by the interlayer insulating layer 197.

The through-plug 790 may extend in the Z-direction and may be in contact with a plurality of back-gate electrodes 150. For example, the through-plug 790 may be disposed on the interface region R3 and may penetrate through the second stack structure ST2. In an example embodiment, the through-plug 790 may include protrusions 792 protruding in the horizontal direction from a side surface of the through-plug 790. For example, the protrusions 792 may extend along the periphery of the through-plug 790. Each of the protrusions 792 may be connected to a corresponding back-gate electrode 150.

In an example embodiment, the semiconductor device 700 may further include isolating insulating layers 712 in contact with a side surface of the through-plug 790. The isolating insulating layers 712 may extend in the horizontal direction along the periphery of the through-plug 790 and may be spaced apart from each other in the Z-direction. The isolating insulating layers 712 may be disposed at levels different from that of the protrusions 792 and the back-gate electrodes 150. The isolating insulating layers 712 may be disposed at the same level as a level of the gate electrodes 140 and may be in contact with the connection pads 170.

Referring to FIG. 14B, a semiconductor device 800 may include a first stack structure ST1 disposed on a memory cell region R1 and a second stack structure ST2 disposed on a contact region R2 and an interface region R3. In an example embodiment, each back-gate electrode 150 may be disposed on a corresponding gate electrode 140.

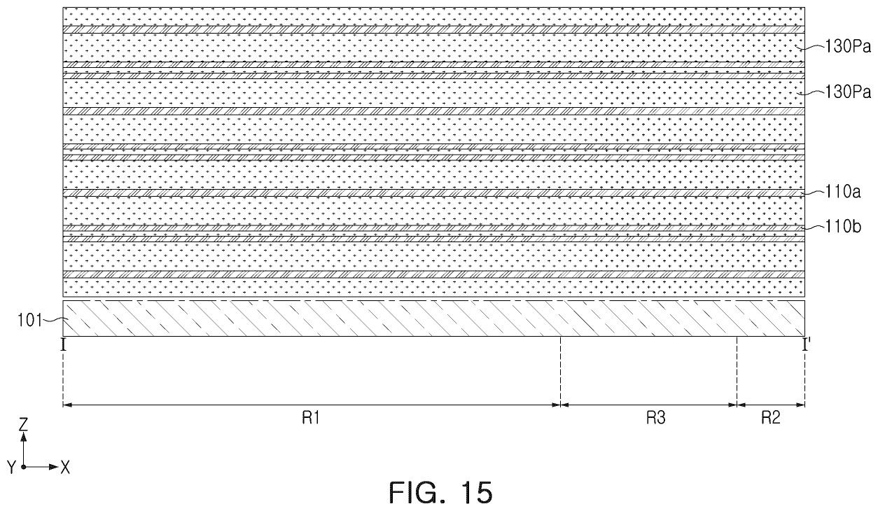

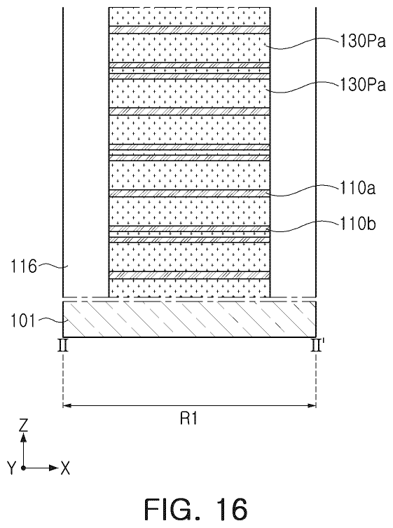

FIGS. 15 to 35 are cross-sectional diagrams illustrating a method of manufacturing a semiconductor device according to an example embodiment. FIGS. 15, 17, 19, 21, 23 and 30 to 33 are vertical cross-sectional diagrams corresponding to FIG. 3A. FIGS. 16, 18, 20, 22, 24 to 29 and 34 to 35 are vertical cross-sectional diagrams corresponding to FIG. 4.

Referring to FIGS. 15 and 16, a substrate 101 including a memory cell region R1, a contact region R2, and an interface region R3 may be prepared.

A first sacrificial layer 110a, a second sacrificial layer 110b and a mold layer 130Pa may be stacked on the substrate 101. The second sacrificial layers 110b may be disposed in a pair and may be spaced apart from each other in the Z-direction, and the first sacrificial layers 110a may be disposed alternately with pairs of the second sacrificial layers 110b. The mold layers 130Pa may be disposed between the first sacrificial layers 110a and the second sacrificial layers 110b. A portion of the mold layers 130Pa may be disposed between the pairs of second sacrificial layers 110b and may have a relatively small thickness. In an example embodiment, the pairs of second sacrificial layers 110b and the mold layer 130Pa therebetween may be replaced with a first sacrificial layer 110a.

The first sacrificial layer 110a and the second sacrificial layer 110b may include a material different from that of the mold layer 130Pa and may include a material having etch selectivity with the mold layer 130Pa. In an example embodiment, the mold layer 130Pa may include silicon, and the first sacrificial layer 110a and the second sacrificial layer 110b may include silicon-germanium, silicon oxide, silicon nitride, silicon carbide, silicon oxynitride, or a combination thereof. In an example embodiment, the mold layer 130Pa may include silicon oxide, and the first sacrificial layer 110a and the second sacrificial layer 110b may include silicon nitride, silicon oxynitride, or a combination thereof.

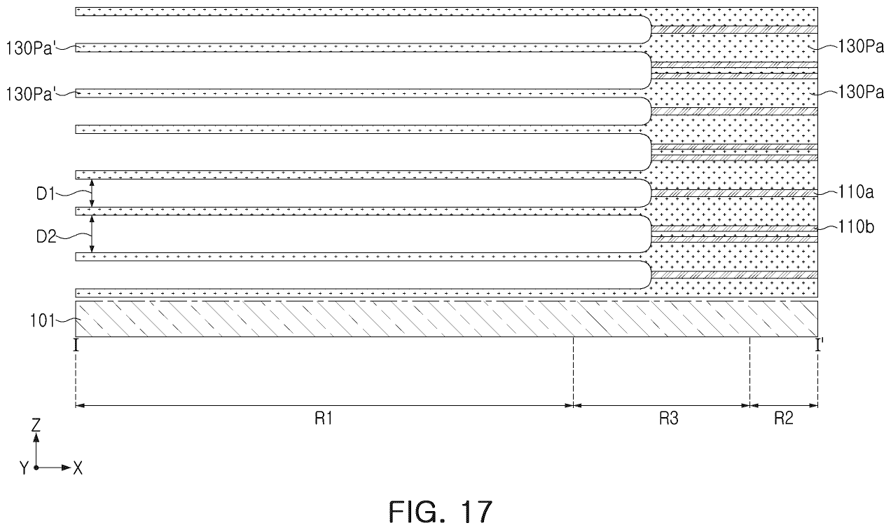

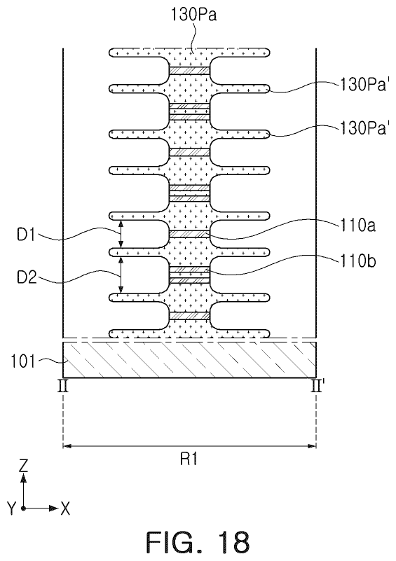

Referring to FIGS. 17 and 18, first and second trenches (t1 and t2 in FIG. 2) may be formed by etching a portion of the first sacrificial layer 110a, the second sacrificial layer 110b and the mold layer 130Pa in the memory cell region R1, and a first preliminary insulating structure (the position of CAP in FIG. 2) and a second preliminary insulating structure (the position 162 in FIG. 2), each having a line shape and filling the first and second trenches may be formed.

In the memory cell region R1, through-holes (the position between the active layers 130 in FIG. 2) may be formed by etching a portion of the first sacrificial layer 110a, the second sacrificial layer 110b and the mold layer 130Pa to expose side surfaces of the first sacrificial layer 110a and the second sacrificial layer 110b. Thereafter, the exposed first sacrificial layer 110a and the exposed second sacrificial layer 110b may be selectively removed from exposed memory cell region R1 and exposed interface region R3. For example, the first sacrificial layer 110a and exposed second sacrificial layer 110b may be selectively removed through through-holes, and the upper and lower surfaces of exposed mold layers 130Pa may be exposed. An etching process may be performed in exposed memory cell region R1 and exposed interface region R3, such that a thickness of the mold layers 130Pa may be reduced and exposed preliminary active layers 130Pa′ may be formed. Among the mold layers of 130Pa, mold layers having a relatively small thickness may be removed. In an example embodiment, a distance between preliminary active layers 130Pa′ may not be constant. For example, the preliminary active layers 130Pa′ adjacent to each other in the Z-direction may be spaced apart from each other by a first distance D1 or a second distance D2 greater than the first distance D1.

In an example embodiment, referring to FIG. 2, a through-hole (the position between the active layers 130 in FIG. 2) may not be formed in a position of the through-plug 190 in FIG. 2 in the memory cell region R1. Accordingly, as illustrated in FIG. 18, in the memory cell region R1, the first sacrificial layer 110a, the second sacrificial layer 110b, and the mold layers 130Pa therebetween may remain without being completely removed.

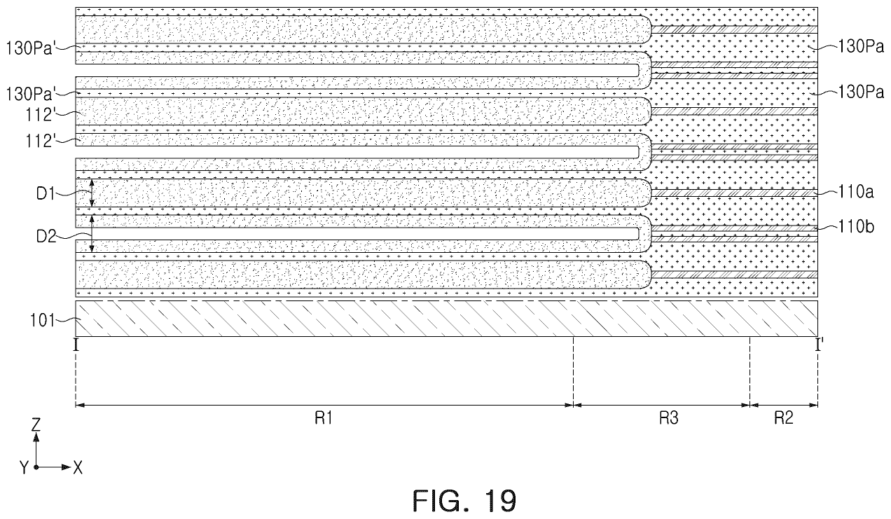

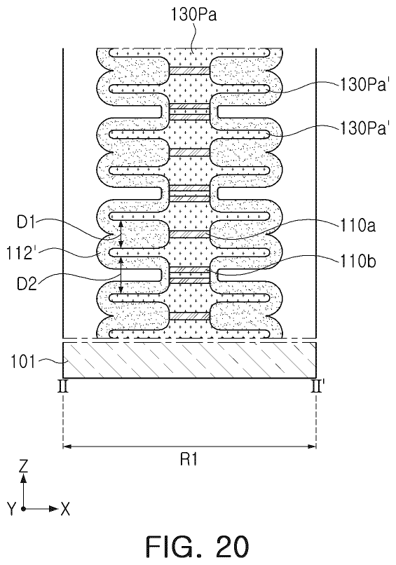

Referring to FIGS. 19 and 20, a first material layer 112′ may be formed between the preliminary active layers 130Pa′. The first material layer 112′ may fill a space between the preliminary active layers 130Pa′ spaced apart from each other at a first distance D1. However, the first material layer 112′ may not completely fill the space between the preliminary active layers 130Pa′ spaced apart from each other at a second distance D2. The first material layer 112′ may include silicon nitride, silicon carbonitride, silicon oxynitride, or a combination thereof.

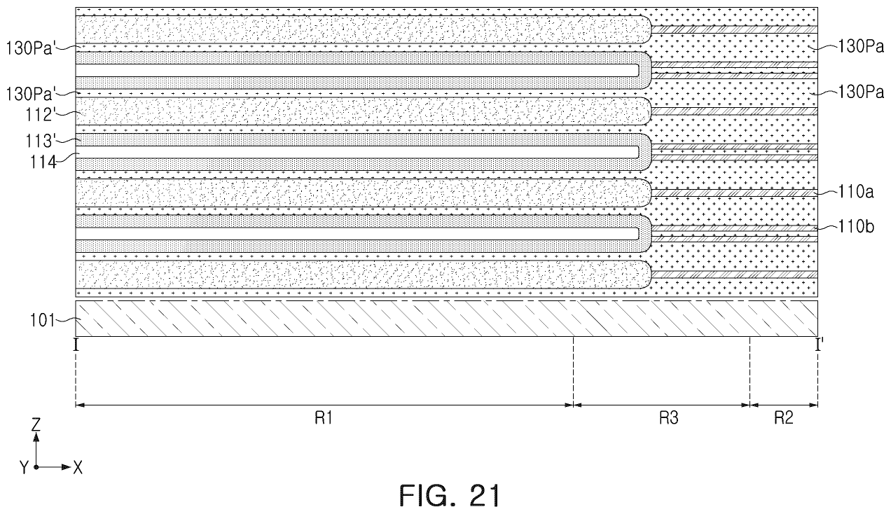

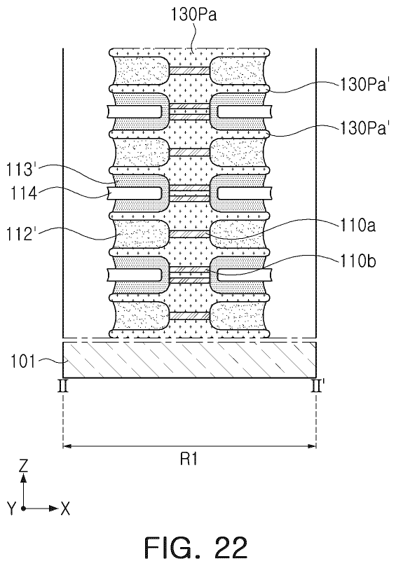

Referring to FIGS. 21 and 22, a portion of the first material layer 112′ may be etched by performing an etching process. For example, an etchant for etching the first material layer 112′ may flow into a space between the preliminary active layers 130Pa′ spaced apart from each other at the second distance D2, and a portion of the first material layer 112′ between the preliminary active layers 130Pa′ spaced apart from each other at the second distance D2 may be removed.

A second material layer 113′ and an interlayer insulating layer 114 may be formed in a space from which a portion of the first material layer 112′ has been removed. The second material layers 113′ may be formed conformally along the preliminary active layers 130Pa′, and the interlayer insulating layer 114 may be disposed in the second material layers 113′. As illustrated in FIG. 22, after the second material layer 113′ and the interlayer insulating layer 114 are formed, the second material layer 113′ and the interlayer insulating layer 114 may be partially etched to expose the preliminary active layers 130Pa′.

The second material layer 113′ may include silicon nitride, silicon carbonitride, silicon oxynitride, or a combination thereof. The interlayer insulating layer 114 may include silicon oxide.

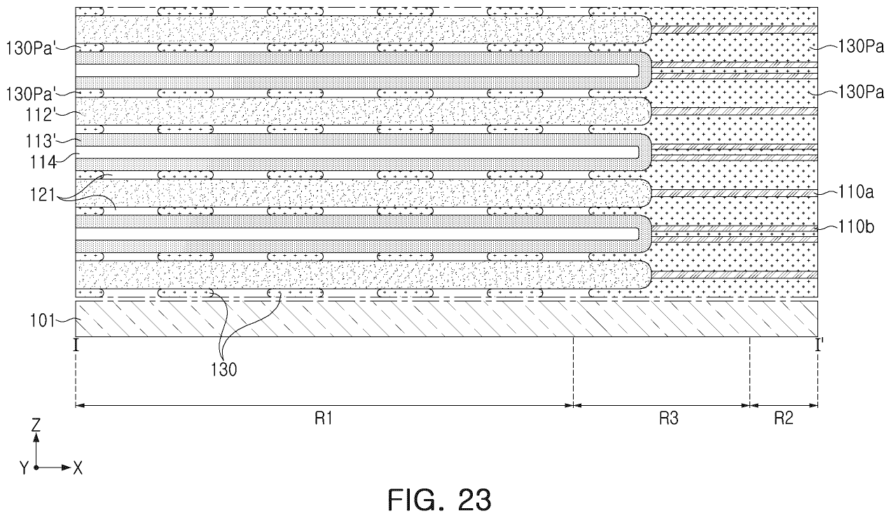

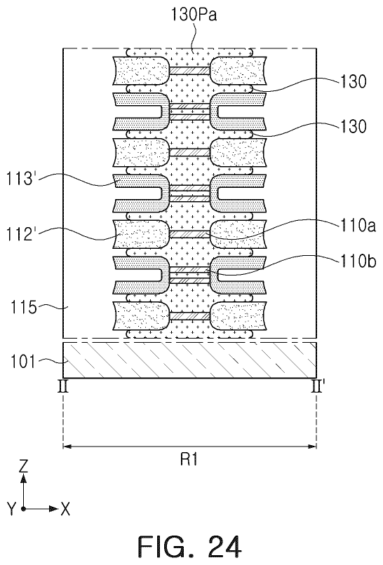

Referring to FIGS. 23 and 24, active layers 130 may be formed by selectively etching the preliminary active layers 130Pa′. For example, the preliminary active layers 130Pa′ may be selectively etched by an etchant flowing through the through-holes (at the position of the insulating pillars 116 in FIG. 2). The active layer 130 may extend in the Y-direction and may be spaced apart from each other in the X-direction.

After the active layers 130 are formed, the first interlayer insulating layers 121 and the interlayer insulating layer 115 may be formed by depositing an insulating material. The first interlayer insulating layers 121 may fill a space between the active layers 130 and may be in contact with the first material layer 112′ and the second material layer 113′.

The insulating material may cover the first material layer 112′, the second material layer 113′ and the interlayer insulating layer 114, and may form the interlayer insulating layer 115. In an example embodiment, the interlayer insulating layer 115 may include the same material as that of the interlayer insulating layer 114.

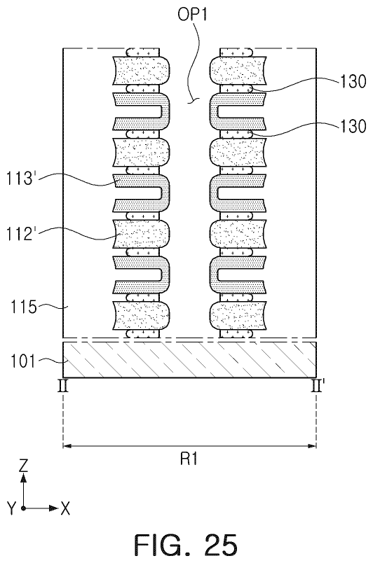

Referring to FIG. 25, the first opening OP1 may be formed in a position of the through-plug 190 in FIG. 2. For example, the first sacrificial layer 110a and the second sacrificial layer 110b between the first material layers 112′ and the second material layers 113′ may be removed, and the active layers 130 may be partially removed. The first opening OP1 may expose side surfaces of first material layers 112′, the second material layers 113′ and the active layers 130.

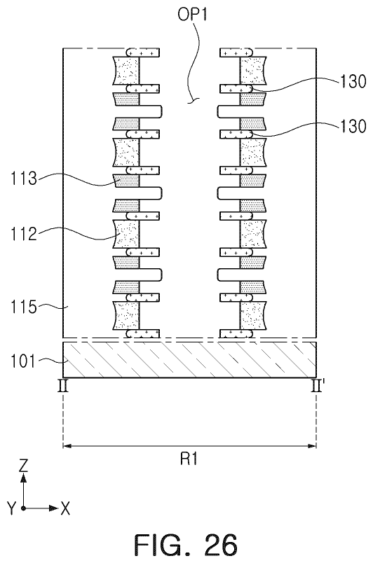

Referring to FIG. 26, the first material layers 112′ and the second material layers 113′ may be etched, and a portion of the interlayer insulating layer 115 may be exposed by a first opening OP1. The first material layers 112′ and the second material layers 113′ may be etched to form an isolating insulating layer 112 and a capping layer 113.

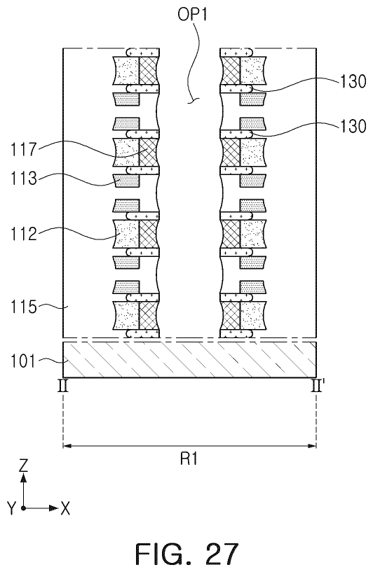

Referring to FIG. 27, an insulating material may be deposited to cover a portion of the exposed interlayer insulating layer 115, and the insulating material may be partially etched to expose the active layers 130. The insulating material may include the same material as that of the interlayer insulating layer 115. The capping layer 113 may be covered by the interlayer insulating layer 115 and may not be exposed by the first opening OP1. The isolating insulating layer 112 may not be completely covered by the interlayer insulating layer 115.

Thereafter, a capping layer 117 may be formed on the isolating insulating layer 112. The capping layer 117 may be formed by depositing an insulating material in the isolating insulating layer 112 and partially etching the insulating material to expose the active layers 130. The capping layer 117 may include a material different from those of the isolating insulating layer 112 and the interlayer insulating layer 115, and may include a material having etch selectivity with the isolating insulating layer 112 and the interlayer insulating layer 115. For example, the capping layer 117 may include silicon nitride, silicon carbonitride, silicon oxynitride, or a combination thereof.

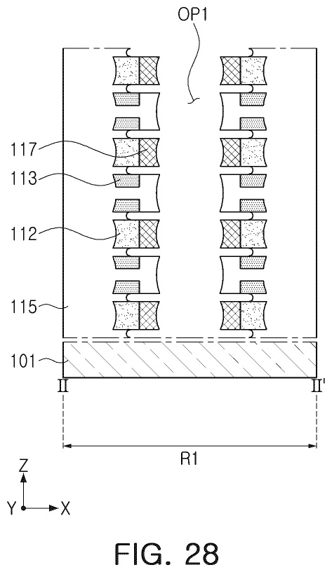

Referring to FIG. 28, the active layers 130 exposed by the first opening OP1 may be selectively removed. The isolating insulating layer 112, the capping layer 113, the interlayer insulating layer 115 and the capping layer 117 may not be etched.

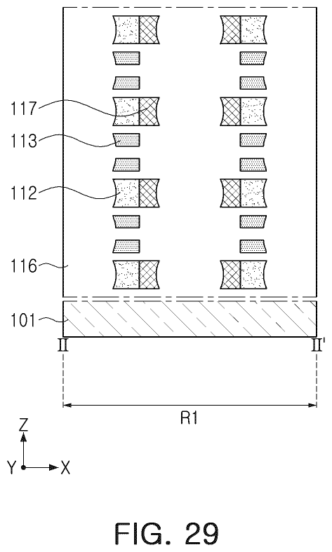

Referring to FIG. 29, an insulating material may be formed to cover the first opening OP1. The insulating material may include the same material as that of the interlayer insulating layer 115, and may form the insulating pillar 116 together with the interlayer insulating layer 115. For example, the insulating pillar 116 may surround the isolating insulating layer 112, the capping layer 113 and the capping layer 117.

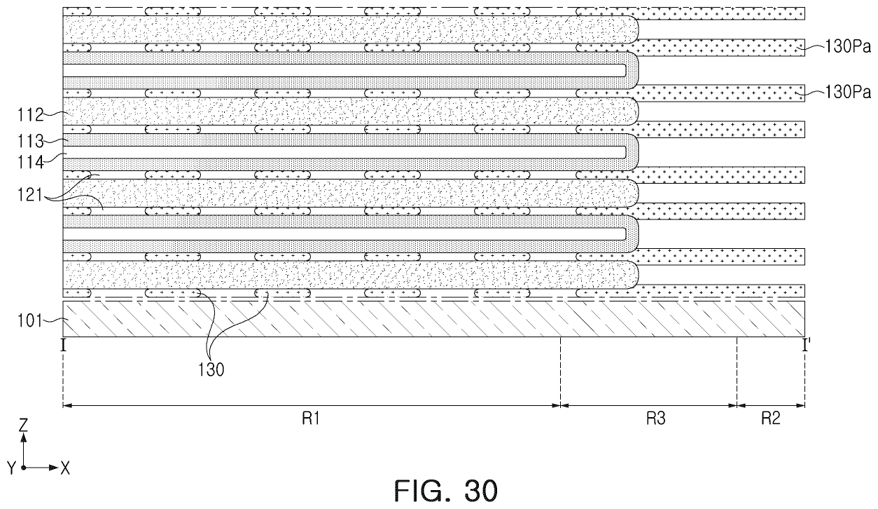

Referring to FIG. 30, third and fourth trenches (t3 and t4 in FIG. 2) may be formed by etching a portion of the first sacrificial layer 110a, the second sacrificial layer 110b and the mold layer 130Pa in the contact region R2 and the interface region R3, and a first preliminary gap-fill insulating pattern (at the position of first gap-fill insulating pattern 172 in FIG. 2) having a line shape and filling the third trench (t3 in FIG. 2) may be formed. Side surfaces of the first sacrificial layer 110a and the second sacrificial layer 110b may be exposed by the fourth trench (t4 in FIG. 2).

Thereafter, the exposed first sacrificial layer 110a and the exposed second sacrificial layer 110b may be selectively removed from exposed contact region R2 and exposed interface region R3. For example, the first sacrificial layer 110a and the second sacrificial layer 110b may be selectively removed through the fourth trench t4, and upper and lower surfaces of the mold layers 130Pa may be exposed. Through the etching process, the isolating insulating layer 112 and the capping layer 113 may be exposed in the interface region R3.

An etching process may be performed in the contact region R2 and the interface region R3, such that the thickness of the mold layers of 130Pa may be reduced. Among the mold layers of 130Pa, mold layers having a relatively small thickness may be removed. In an example embodiment, a distance between the mold layers 130Pa may not be constant.

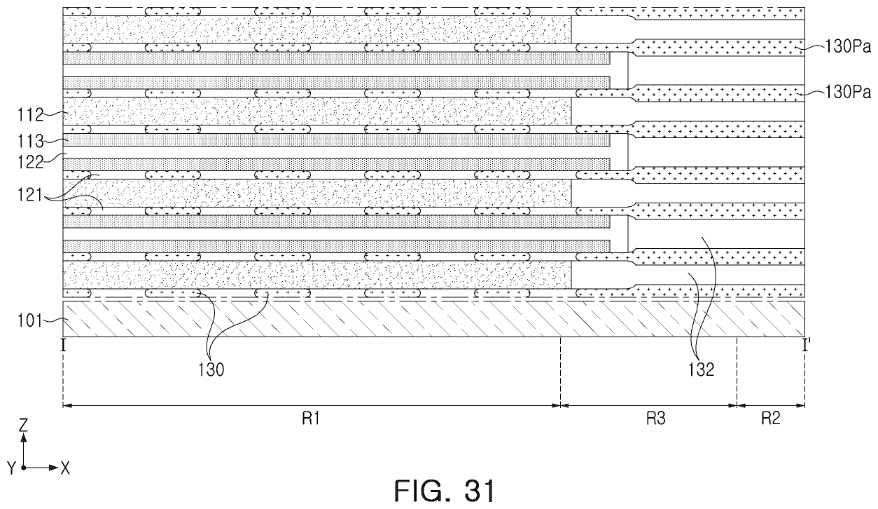

Referring to FIG. 31, an etching process may be performed, and ends of the exposed isolating insulating layer 112 and the exposed capping layer 113 may be partially etched.

An insulating material may be deposited and may cover the ends of the isolating insulating layer 112 and the capping layer 113, and the insulating material may be partially etched to expose the ends of the isolating insulating layer 112. In a region in which the distance between the mold layers 130Pa is relatively large, the insulating material may not be completely removed and may cover the end of the capping layer 113. The insulating material may include the same material as that of the interlayer insulating layer 114, and may form a second interlayer insulating layer 122 together with the interlayer insulating layer 114.

Connection insulating layers 132 may be formed by depositing an insulating material in a region between the mold layers 130Pa. The connection insulating layers 132 may completely fill a space between the mold layers 130Pa. The connection insulating layers 132 may include silicon oxide, silicon nitride, silicon oxynitride, or a combination thereof.

Through the deposition process, a second gap-fill insulating pattern (174 in FIG. 2) filling the fourth trench (t4 in FIG. 2) may be formed.

In an example embodiment, the mold layers 130Pa and the connection insulating layers 132 may be patterned to have a staircase structure in the contact region R2. In some example embodiments, the mold layers 130Pa and the connection insulating layers 132 may be patterned in different processes.

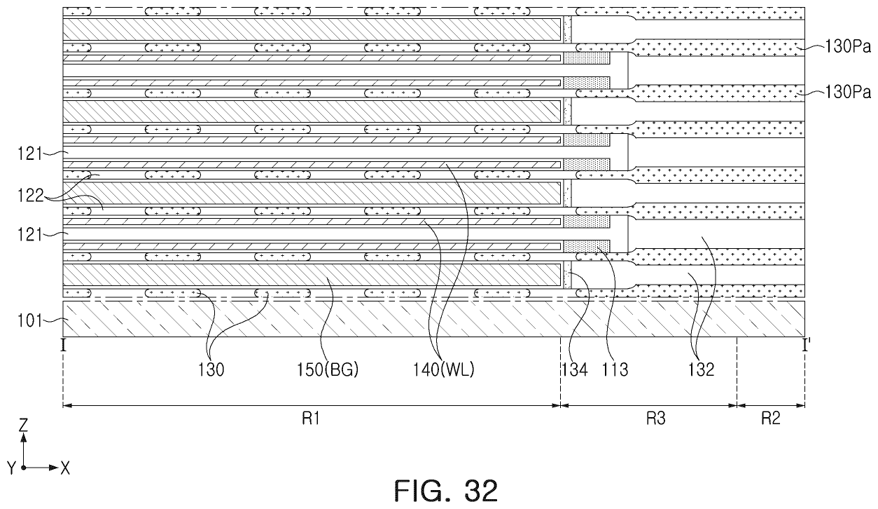

Referring to FIG. 32, the isolating insulating layer 112 and the capping layer 113 may be replaced with gate structures 140 and 150 in the memory cell region R1. For example, the second preliminary insulating structure (at the position of the insulating structure 162 in FIG. 2) disposed in the second trench (t2 in FIG. 2) may be removed, and side surfaces of the isolating insulating layer 112 and the capping layer 113 may be exposed.

The isolating insulating layer 112 and the capping layer 113 may be removed from the memory cell region R1, and the back-gate electrode 150 and the gate electrode 140 may be formed in spaces from which the isolating insulating layer 112 and the capping layer 113 are removed, respectively. Gate dielectrics 145 and 155 may be formed before the gate structures 140 and 150 are formed, and the gate dielectric layer 145 and the back-gate dielectric layer 155 may surround the gate electrode 140 and the back-gate electrode 150, respectively.

In an example embodiment, an insulating layer 134 in contact with a back-gate dielectric layer 155 surrounding the back-gate electrode 150 may be formed in the interface region R3. The insulating layer 134 may be a portion of the isolating insulating layer 112 or may be an insulating material formed after the isolating insulating layer 112 is removed. A portion of the capping layer 113 may be in contact with the gate dielectric layer 145 surrounding the gate electrode 140 in the interface region R3.

Thereafter, vertical conductive patterns 160 may be formed by depositing a conductive material on an internal wall of the second trench (t2 in FIG. 2) and isolating the conductive patterns spaced apart from each other in the X-direction. After the vertical conductive patterns 160 are formed, an insulating structure (162 in FIG. 2) covering the vertical conductive patterns 160 may be formed, and the insulating structure 162 may fill a second trench T2.

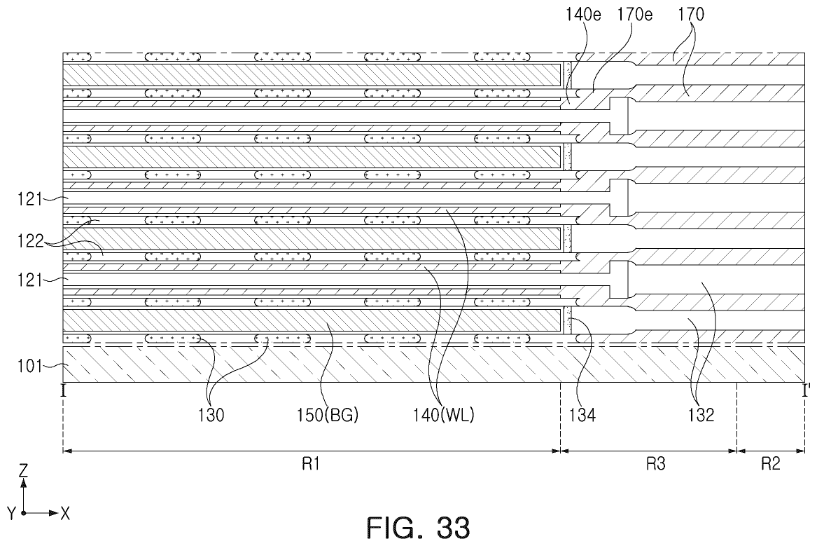

Referring to FIG. 33, the mold layers 130Pa may be replaced with connection pads 170 in the contact region R2 and the interface region R3. For example, the first preliminary gap-fill insulating pattern (at the position of the gap-fill insulating pattern 172 in FIG. 2) disposed in the third trench (t3 in FIG. 2) may be removed, and side surfaces of the mold layers 130Pa and the connection insulating layers 132 may be exposed. The mold layers 130Pa may be removed such that the capping layer 113 may be exposed, and the capping layer 113 may be removed such that the gate dielectric layer 145 may be exposed.

Connection pads 170 may be formed by partially etching the exposed gate dielectric layer 145 and depositing a conductive material. The connection pads 170 may extend in the X-direction and may be spaced apart from each other in the Z-direction. The connection pads 170 may be connected to corresponding gate electrodes 140, respectively. For example, in the interface region R3, an end 140e of the gate electrode 140 may be in contact with an end 170e of the connection pad 170. In an example embodiment, the gate electrodes 140 may be disposed at levels different from levels of the corresponding connection pads 170, respectively, but example embodiments are not limited thereto.

After the connection pads 170 are formed, a first gap-fill insulating pattern (the first gap-fill insulating pattern 172 in FIG. 2) covering side surfaces of the connection pads 170 may be formed in the third trench t3. The first gap-fill insulating pattern 172 may fill the third trench t3.

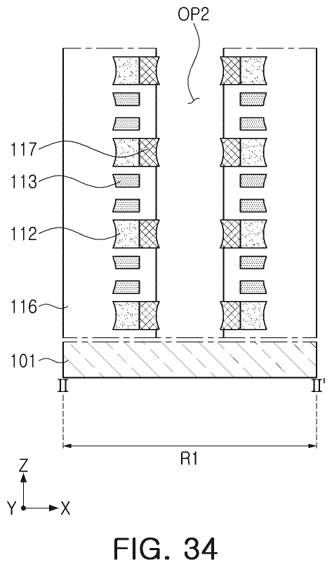

Referring to FIG. 34, a second opening OP2 may be formed in the memory cell region R1. The second opening OP2 may be formed in the same position as the first opening OP2. For example, the insulating pillar 116 may be etched by methods such as an anisotropic etching process and an isotropic etching process, and the capping layer 117 may be exposed.

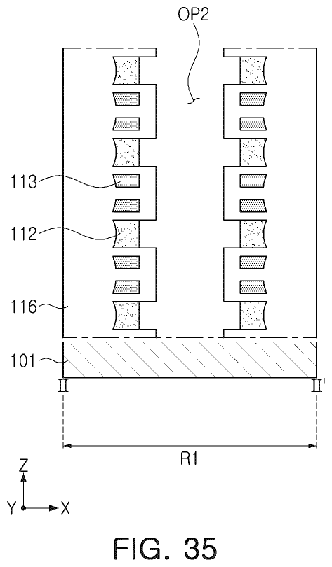

Referring to FIG. 35, the capping layer 117 may be selectively removed and the isolating insulating layer 112 may be exposed. The isolating insulating layer 112 may include a material having an etch selectivity with the capping layer 117, and the isolating insulating layer 112 may not be removed when the capping layer 117 is removed. The capping layer 117 may be disposed at the same level as a level of the back-gate electrode 150, and the capping layer 117 may be removed such that the back-gate dielectric layer 155 covering the back-gate electrode 150 may be exposed.

Referring back to FIGS. 4 and 6, the through-plug 190 may be formed by filling the second opening OP2 with a conductive material. Before the through-plug 190 is formed, the exposed back-gate dielectric layer 155 may be partially etched. Thereafter, the through-plug 190 may be formed, and the through-plug 190 may be in contact with and electrically connected to the back-gate electrode 150. For example, the through-plug 190 may extend in the Z-direction, and the plurality of back-gate electrodes 150 may be in contact with and electrically connected to the through-plug 190.

Referring again to FIGS. 2 and 5, the first preliminary insulating structure (at the position of CAP in FIG. 2) filling the first trench T1 may be removed, and the capacitor structure CAP may be formed in the first trench T1.

A contact plug 195 may be formed on the connection pad 170 in the contact region R2, such that the semiconductor device 100 may be manufactured.

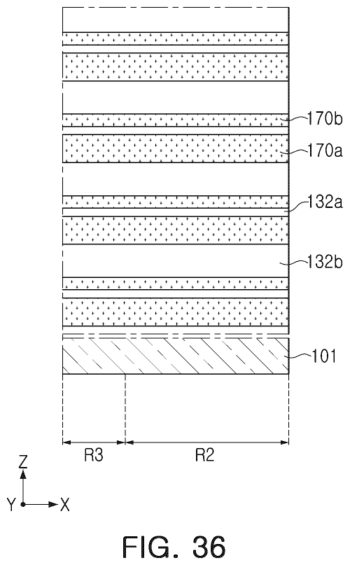

FIGS. 36 to 41 are cross-sectional diagrams illustrating a method of manufacturing a semiconductor device according to an example embodiment. Specifically, FIGS. 36 to 41 are vertical cross-sectional diagrams corresponding to FIG. 14A.

Referring to FIG. 36, a first sacrificial layer 170a, a second sacrificial layer 170b, a first mold layer 132a and a second mold layer 132b may be stacked on a substrate 101. The first sacrificial layer 170a and the second sacrificial layer 170b may be disposed alternately in the Z-direction. The first mold layer 132a and the second mold layer 132b may be disposed alternately in the Z-direction and may be disposed between the first sacrificial layer 170a and the second sacrificial layer 170b. The first sacrificial layer 170a may have a thickness greater than that of the second sacrificial layer 170b, and the first mold layer 132a may have a thickness greater than that of the second mold layer 132b.

The first sacrificial layer 170a and the second sacrificial layer 170b may include a different material from those of the first mold layer 132a and the second mold layer 132b. In an example embodiment, the first mold layer 132a and the second mold layer 132b may include silicon oxide, and the first sacrificial layer 170a and the second sacrificial layer 170b may include silicon nitride, silicon oxynitride, or a combination thereof.

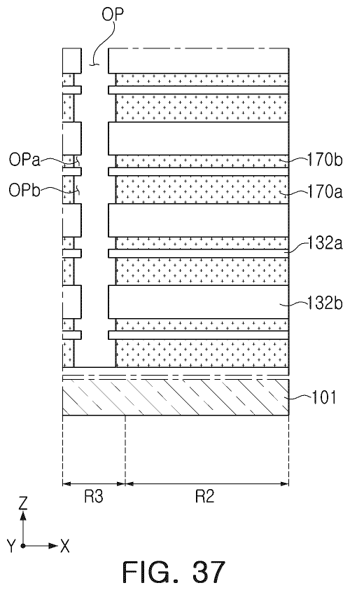

Referring to FIG. 37, an opening OP may be formed on an interface region R3. For example, the first sacrificial layer 170a, the second sacrificial layer 170b, the first mold layer 132a and the second mold layer 132b may be etched by an anisotropic etching process. Thereafter, the first sacrificial layer 170a and the second sacrificial layer 170b may be further etched in the horizontal direction by an isotropic etching process, thereby forming an opening OP. A first space OPa and a second space OPb may be formed through the isotropic etching process. The first space OPa may be disposed between the first sacrificial layer 170a and the second sacrificial layer 170b and may expose a side surface of the second sacrificial layer 170b. The second space OPb may be disposed between the first sacrificial layer 170a and the second sacrificial layer 170b and may expose a side surface of the first sacrificial layer 170a. A vertical width of the second space OPb may be larger than a vertical width of the first space OPa. A horizontal width of the second space OPb may be the same as a horizontal width of the first space OPa, but an example embodiments are not limited thereto. In some example embodiments, a horizontal width of the second space OPb may be greater than a horizontal width of the first space OPa.

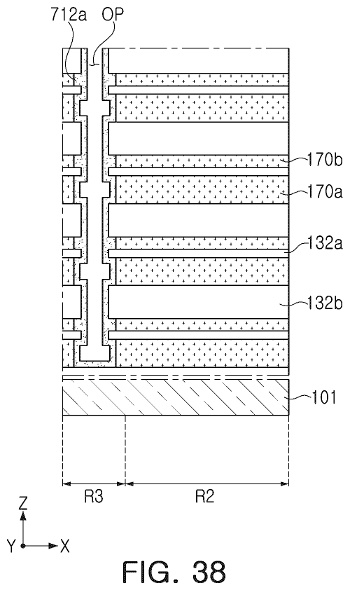

Referring to FIG. 38, an insulating layer 712a may be formed in the opening OP. For example, the insulating layer 712a may be formed conformally along an internal wall of the opening OP and may be in contact with the first sacrificial layer 170a, the second sacrificial layer 170b, the first mold layer 132a and the second mold layer 132b. In an example embodiment, the insulating layer 712a may completely fill the first space OPa, and may not completely fill the second space OPb. The insulating layer 712a may include silicon nitride, silicon oxynitride, or a combination thereof.

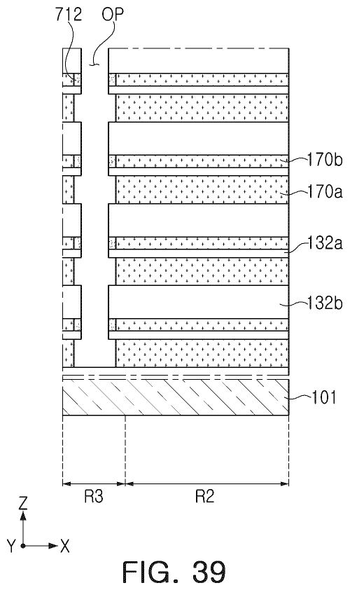

Referring to FIG. 39, an isolating insulating layer 712 may be formed by etching the insulating layer 712a by performing an etching process. The etching process may include an anisotropic etching process, an isotropic etching process, or a combination thereof. Through the etching process, a side surface of the first sacrificial layer 170a may be exposed, and a side surface of the second sacrificial layer 170b may not be exposed and may be covered by the isolating insulating layer 712.

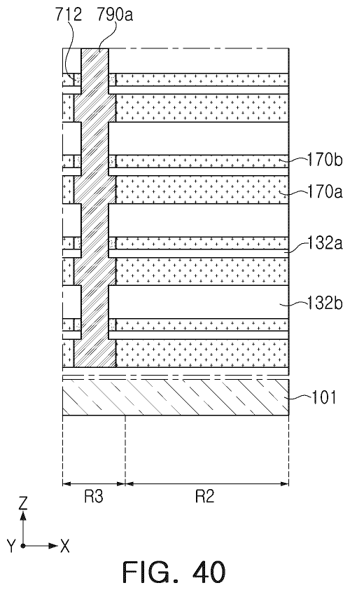

Referring to FIG. 40, a filling layer 790a may be formed by filling the opening OP with an insulating material. The filling layer 790a may include a material having an etch selectivity with a first sacrificial layer 170a, a second sacrificial layer 170b, a first mold layer 132a, a second mold layer 132b and an isolating insulating layer 712. In an example embodiment, the filling layer 790a may include silicon oxide, silicon nitride, silicon oxynitride, polysilicon, or a combination thereof.

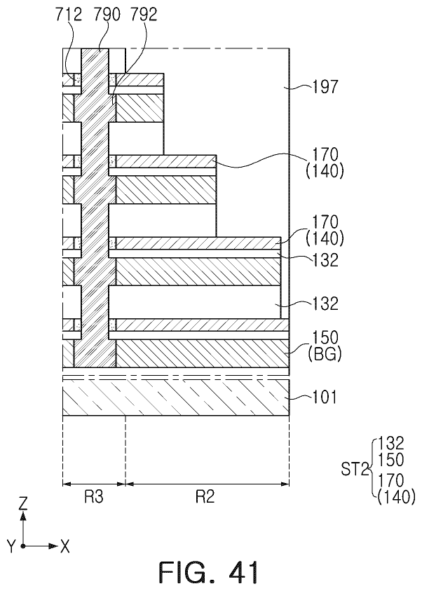

Referring to FIG. 41, the first sacrificial layer 170a, the second sacrificial layer 170b, the first mold layer 132a and the second mold layer 132b may be patterned to have a staircase structure on the contact region R2. Through the patterning process, the first mold layer 132a and the second mold layer 132b may be patterned, thereby forming connection insulating layers 132. The first sacrificial layer 170a and the second sacrificial layer 170b may be removed and a conductive material may be filled therein, thereby forming the back-gate electrodes 150 and the connection pads 170. The back-gate electrodes 150, the connection pads 170 and the connecting insulating layers 132 may form the second stack structure ST2. An interlayer insulating layer 197 covering the second stack structure ST2 may be formed.

Referring again to FIG. 14A, the through-plug 790 may be formed by removing the filling layer 790a and filling a conductive material therein. The through-plug 790 may include protrusions 792 in contact with the back-gate electrodes 150. The semiconductor device 700 may be manufactured by forming the contact plugs 195 penetrating the interlayer insulating layer 197 and in contact with the connection pads 170.

According to the aforementioned example embodiments, the through-plug may extend in a vertical direction and may be connected to a plurality of back-gate electrodes. Because the plurality of back-gate electrodes are connected to each other by a through-plug, a size of the semiconductor device may be reduced.

While some example embodiments have been illustrated and described above, it will be configured as apparent to those skilled in the art that modifications and variations may be made without departing from the scope as defined by the appended claims.

What is claimed is:

1. A semiconductor device, comprising:
a substrate including a memory cell region, a contact region and an interface region between the memory cell region and the contact region;
gate electrodes extending in a first horizontal direction on the memory cell region and stacked and spaced apart from each other in a vertical direction;
back-gate electrodes extending between the gate electrodes in the first horizontal direction and stacked and spaced apart from each other in the vertical direction;
vertical conductive patterns extending in the vertical direction and spaced apart from each other in the first horizontal direction on the memory cell region;
active layers between the gate electrodes and the back-gate electrodes, the active layers extending in a second horizontal direction intersecting with the first horizontal direction, the active layers electrically connected to the vertical conductive patterns on the memory cell region; and
a through-plug extending in the vertical direction and in contact with side surfaces of the back-gate electrodes.

2. The semiconductor device of claim 1, wherein the through-plug electrically connects the back-gate electrodes to each other.

3. The semiconductor device of claim 1, wherein the through-plug is not electrically connected to the gate electrodes.

4. The semiconductor device of claim 1, wherein the through-plug includes protrusions protruding in a horizontal direction and spaced apart from each other in the vertical direction.

5. The semiconductor device of claim 4, wherein the protrusions are in contact with the back-gate electrodes.

6. The semiconductor device of claim 4, further comprising:
isolating insulating layers being at a same level as a level of the back-gate electrodes,
wherein a portion of the protrusions is in contact with the isolating insulating layers.

7. The semiconductor device of claim 1, further comprising:
back-gate dielectric layers covering corresponding ones of the back-gate electrodes, respectively,
wherein the through-plug is in contact with the back-gate dielectric layers.

8. The semiconductor device of claim 7, wherein the back-gate electrodes include a first side surface covered by the back-gate dielectric layers and a second side surface opposite to the first side surface and in contact with the through-plug.

9. The semiconductor device of claim 1, wherein the through-plug is on the memory cell region.

10. The semiconductor device of claim 9, further comprising:
a capacitor structure electrically connected to the active layers,
wherein the active layers are between the vertical conductive patterns and the capacitor structure, and
wherein the through-plug is between the gate electrodes and the capacitor structure.

11. The semiconductor device of claim 1, wherein a thickness of the back-gate electrodes is greater than a thickness of the gate electrodes.

12. The semiconductor device of claim 1, wherein the through-plug is on the interface region.

13. The semiconductor device of claim 12, further comprising:
isolating insulating layers being at a same level as a level of the gate electrodes and in contact with the through-plug,
wherein the through-plug includes protrusions protruding in a horizontal direction and spaced apart from each other in the vertical direction.

14. The semiconductor device of claim 12, wherein the back-gate electrodes extend from the memory cell region to the contact region.

15. A semiconductor device, comprising:
a substrate including a memory cell region, a contact region and an interface region between the memory cell region and the contact region;
stack structures extending in a first horizontal direction and spaced apart from each other in a second horizontal direction intersecting with the first horizontal direction, the stack structures including first stack structures on the memory cell region and second stack structures on the interface region and the contact region, the second stack structures electrically connected to the first stack structures; and
through-plugs penetrating the stack structures in a vertical direction,
wherein the first stack structures include,
gate electrodes extending in the first horizontal direction and stacked and spaced apart from each other in the vertical direction;
back-gate electrodes extending in the first horizontal direction between the gate electrodes and stacked and spaced apart from each other in the vertical direction; and
active layers between the gate electrodes and the back-gate electrodes, the active layers including channel regions extending in the second horizontal direction and overlapping the gate electrodes in the vertical direction, and
wherein the through-plugs are electrically connected to the back-gate electrodes.

16. The semiconductor device of claim 15, further comprising:
isolation layers in the memory cell region and between the first stack structures,
wherein each of the active layers includes a first source/drain region and a second source/drain region, each of the isolation layers includes a vertical conductive pattern electrically connected to the first source/drain region of one of the active layers, or a capacitor structure electrically connected to the second source/drain region of one of the active layers.

17. The semiconductor device of claim 15,
wherein the through-plugs penetrate through the second stack structures in the vertical direction on the interface region, and
wherein the through-plugs are at both sides of each of the first stack structures.

18. The semiconductor device of claim 17, wherein the through-plugs partially overlap the second stack structures in the vertical direction.

19. The semiconductor device of claim 15, wherein, in a plan view, the through-plugs are in a zigzag pattern in the second horizontal direction.

20. A semiconductor device, comprising:
a substrate including a memory cell region, a contact region and an interface region between the memory cell region and the contact region;
gate electrodes extending in a first horizontal direction on the memory cell region and stacked and spaced apart from each other in a vertical direction;
back-gate electrodes extending in the first horizontal direction between the gate electrodes and stacked and spaced apart from each other in the vertical direction;
vertical conductive patterns extending in the vertical direction and arranged and spaced apart from each other in the first horizontal direction on the memory cell region;
active layers between the gate electrodes and the back-gate electrodes, the active layers extending in a second horizontal direction intersecting with the first horizontal direction, the active layers electrically connected to the vertical conductive patterns on the memory cell region;
a capacitor structure electrically connected to the active layers;
a through-plug extending in the vertical direction and in contact with side surfaces of the back-gate electrodes; and
contact plugs on the contact region and electrically connected to the gate electrodes,
wherein the through-plug is offset from an axis of a corresponding one of the gate electrodes running in the first horizontal direction by connecting center points thereof in the second horizontal direction, on the memory cell region, and
wherein the through-plug has a first horizontal width at a same level as a level of the gate electrodes and a second horizontal width greater than the first horizontal width at a same level as a level of the back-gate electrodes.
